(19) United States
(12) Patent Application Publication
(10) Pub. No.: US 2008/0230838 A1
(43) Pub. Date: Sep. 25, 2008

(54) Semiconductor memory device and manufacturing process therefore

(75) Inventor: Shinji Ohara, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/073,239

(22) Filed: Mar. 3, 2008

(30) Foreign Application Priority Data
Mar. 8, 2007 (JP) 2007-058799

(51) Int. Cl. H01L 27/12; H01L 21/84

(52) U.S. Cl. 257/350; 438/151; 257/E27.112; 257/E21.7

(57) ABSTRACT

An objective of this invention is to solve the problem caused by a difference in a silicon layer film thickness between a memory cell region and a region other than the memory cell region.

For solving the problem, while maintaining a structure where an MOS type transistor in a memory cell region is in a floating state and an MOS type transistor in the region other than the memory cell region is not in a floating state, a film thickness of semiconductor layers having a body regions is made equal in these MOS type transistors.

This application is based upon and claims the benefit of priority from Japanese Patent Application No. 2007-058799, filed on Mar. 8, 2007, the disclosure of which is incorporated herein in its entirety by reference.

### BACKGROUND OF THE INVENTION

1. Field of the Invention

The present invention relates to a semiconductor memory device comprising a capacitorless DRAM in which one memory cell is made up of one transistor and comprising an SOI type substrate and a process for manufacturing a semiconductor memory device.

2. Description of the Related Art

### Memory Cell Manufactured Using a Related Floating-Body Type MOS Transistor

In a related DRAM (Dynamic Random Access Memory), one memory cell is made up of a combination of one MOS transistor and one capacitor. As a design rule has been increasingly size-reduced for achieving highly integrated DRAM, processing of, for example, a capacitor has become more difficult. There has been, therefore, suggested a capacitorless DRAM in which one memory cell is made up of one transistor, as a DRAM which can be easily processed and has a simpler structure.

A typical example of such a memory cell structure employs a floating-body type MOS transistor as disclosed in Japanese Laid-open Patent Publication No. 2003-68877. There will be described a floating-body type transistor used as a memory cell in a related capacitorless DRAM with reference to the drawings.

FIG. 1 is a cross-sectional view illustrating the structure of a related floating-body type transistor. In this figure, 101 is an SOI (Silicon On Insulator) type semiconductor substrate, comprising a silicon (Si) substrate 102 for holding, a silicon oxide layer (SiO₂) 103 formed on the silicon substrate 102 as an insulating layer, and an upper silicon layer 111 on the silicon oxide layer 103.

Then, 104 and 105 are silicon oxide films for isolations and formed such that they extend over the whole length in a thickness direction from the surface of the silicon layer 111 to the bottom of the silicon oxide layer 103. These isolation regions 104, 105 are disposed such that they completely surround the periphery of the transistor. Furthermore, 106 is a gate insulating film for the transistor, and 107 is a gate electrode.

In the silicon layer 111 on both sides of the gate electrode, dopant diffusion layers containing an N-type dopant such as phosphorous are formed. The dopant diffusion layers act as source/drain regions 109, 110 of the transistor. These source/drain regions 109, 110 are disposed such that they extend over the whole length in a thickness direction from the surface of the silicon layer 111 to the bottom of the silicon oxide layer 103. Furthermore, the region immediately beneath of the gate electrode 107 within this silicon layer 111 is a body region 108 of the transistor containing a P-type dopant such as boron.

When this transistor is in ON state, a channel is formed within the body region 108, and a current flows between the source and the drain regions. The periphery of the body region 108 is surrounded by the source/drain regions 109, 110 with opposite conductivity types and the isolation regions 104, 105, and the bottom of the body region 108 is insulated by the silicon oxide layer 103, so that the transistor is electrically in a completely floating state.

When using this floating-body type transistor as a memory cell, an operation method is as follows.

First, the source region is set at a ground potential (GND potential) while a positive voltage is applied to the drain region and the gate electrode to make the transistor in ON state for a large current. Here, the current causes impact ionization near the drain region, so that holes as a majority carrier in the body region are accumulated in the body region. Then, by applying an appropriate voltage to the gate electrode and the drain region, the state of hole accumulation can be held for a certain period. The accumulated holes can be discharged outwardly by applying a negative voltage to the drain region. The information can be stored by such presence or absence of accumulated holes within the body region.

The presence or absence of such hole accumulation is determined utilizing variation in a threshold voltage of a transistor due to substrate bias effect depending on the presence or the absence of hole accumulation in the body region (in the state of hole accumulation, a threshold voltage is lower than that in the absence of hole accumulation). That is, a voltage applied to the gate electrode and the drain region is regulated to generate so small current to avoid new impact ionization. The presence or absence of hole accumulation can be detected by determining a level of the threshold voltage in such state. By thus determining the presence or absence of hole accumulation within the body region, it can be used as a memory having one bit information.

The holes accumulated in the body region gradually decrease due to a leak current, and, therefore, periodic refreshing is necessary. Thus, a memory device using this floating-body type transistor operates as a DRAM.

### Layout of a Related Memory Device

Next, a layout of a memory device having a floating-body type N-channel transistor as a memory cell is shown. FIG. 2 is a schematic plan view of the configuration of the memory cell. In this figure, 120 is an isolation region, which is formed by STI (Shallow Trench Isolation) where a trench formed in a semiconductor substrate is buried with, for example, a silicon oxide film.

A dopant diffusion layer region 122 is defined in a reticular pattern by regularly disposing the isolation regions 120 on the semiconductor substrate. In this figure, 123 is a gate electrode for the transistor and operates as a word line (WL). For illustration, the word lines 123 are numbered as WL1 to WL4 starting from the left. Furthermore, in a direction perpendicular to the word line 123, an interconnection layer, in addition to the gate electrode, is disposed as a bit line (BL) 124. For illustration, the bit lines 124 are numbered as BL1 and BL2 starting from the top.

Although only six isolation regions (120), four word lines (WL1 to 4) and two bit lines (BL1 to 2) are illustrated for simplicity in FIG. 2, such a pattern is repeatedly located in a practical memory cell. In the memory device in FIG. 2, the region 125 surrounded by a broken line is one memory cell, which can retain one bit information.

There will be, as an example, illustrated the memory cell region 125 for describing the structure of a transistor constituting this memory cell. The diffusion layer region 122 surrounded by the word lines WL1 and WL2 and the isolation region 120 is of N-type and operates as a drain region for the transistor, and shares a contact plug for drain region 121 with an adjacent cell. This contact plug for drain region 121 is connected to the bit line BL2.

The diffusion layer region 122 surrounded by the word lines WL2 and WL3 is of N-type and operates as a source region common to each memory cell at a ground potential (GND potential) 126. The diffusion layer region immediately beneath the word line WL2 is of P-type, and operates as a body region for the transistor (108 in FIG. 1).

In the memory device in FIG. 2, the other memory cells have the same configuration as that in the above memory cell. Specifically, both isolation region 120 and N-type diffusion layer region 122 are formed such that they extend over the length in a thickness direction from the surface of the silicon layer (111 in FIG. 1) and the bottom of the silicon oxide layer (103 in FIG. 1), and the P-type diffusion layer in the body region is electrically in a floating state.

As described above, a memory cell in a capacitorless DRAM can retain information by putting the body region of the transistor into a floating state. However, this floating structure becomes problematical for regions other than a memory cell (for example, a sense amplification circuit, a peripheral circuitry for input/output and a protection circuit for input/output).

That is, when a body region is floating in a MOS type transistor used in the regions other than a memory cell, substrate bias effect occurs due to carrier accumulation as in a memory cell region, leading to variation in a threshold voltage of the transistor. Thus, circuit operation is so unstable that desired functions cannot be fulfilled or an operation current becomes larger, leading to increase in a consumption current.

Thus, for solving such problems, it is necessary to make a structure where only a transistor in a memory cell region has a floating state in a body region while transistors disposed in the other regions have a fixed potential in a body region.

Here, as a helpful structure for solving the above problems, there may be mentioned a structure where on the same semiconductor chip are formed a complete depletion type transistor in which a potential is in a floating state and a partial depletion type transistor in which a potential is fixed. A complete depletion type transistor is a kind of floating-body type transistor, in which in an OFF state of the transistor, a body region is a completely depleted region.

As an alternative structure other than the structure described above, Japanese Laid-open Patent Publication No. 2003-124345 has suggested that a film thickness of a silicon layer formed on an insulating layer in an SOI type substrate is different between a region where a complete depletion type transistor is to be formed and a region where a partial depletion type transistor is to be formed, for achieving a structure where on the same semiconductor chip are formed a complete depletion type transistor in which a potential is in a floating state and a partial depletion type transistor in which a potential is fixed.

As described above, for ensuring stable operation of a capacitorless DRAM formed on an SOI type substrate, it is necessary to make a structure where a body region in an MOS type transistor used for a memory cell region is electrically in a floating state while a body region in an MOS type transistor used in a region other than a memory cell region is not in a floating state.

As a helpful structure, there may be mentioned a structure where a complete depletion type transistor and a partial depletion type transistor are formed on the same semiconductor chip. However, a complete depletion type transistor functions only as a switching element like a common MOS type transistor. On the other hand, in a memory cell region of the present invention, it must serve not only as a switching element but also a memory element by itself. Therefore, in a floating-body type transistor for a capacitorless DRAM used in the present invention, holes as a carrier in a body region must be accumulated to avoid complete depletion in the body region. Thus, a semiconductor device as described above in which both complete depletion type and partial depletion type transistors are formed cannot be applied to the present invention.

Apart form the above structure, it would be speculated that as disclosed in Japanese Laid-open Patent Publication No. 2003-124345, a silicon layer film is made thin for a memory cell for a capacitorless DRAM and thick for the other regions by applying the method partially varying a film thickness of the silicon layer. Such a structure allows for making a structure where a transistor in a memory cell region is in a floating state while in a transistor disposed in a region other than a memory cell, a potential in a body region is fixed. However, it may cause another problem in terms of size reduction as described below. When a film thickness of a silicon layer in the surface of the SOI type substrate (an upper part of an insulating layer within the substrate) is different in a memory cell region from that in a region other than a memory cell, specifically when a silicon layer in a region other than a memory cell region is thicker than that in the memory cell region, a height of the surface of the silicon layer as determined from the rear surface of the SOI type substrate is mutually different between these regions. As a result, a variety of problems as described below are caused during production, making it considerably difficult to produce a fine device with a higher integration degree.

For example, when trying to form a buried insulating film in an STI for isolation by CMP (Chemical Mechanical Polishing), polishing cannot be uniformly performed due to a difference in a surface height between these regions and, therefore, a desired shape cannot be obtained. Furthermore, when a pattern is formed using a photolithography film, focus deviation occurs between regions having different surface heights during exposure, so that a pattern cannot be formed precisely in accordance with the mask shape. Such manufacturing problems due to a height difference in substrate surface regions become more significant, as size reduction proceeds and an allowance in, for example, a dimension or film thickness in a manufacturing process becomes narrower. Therefore, it is difficult to promote size reduction.

Thus, for solving the above manufacturing problems to produce a device with a higher integrity degree, it is essential that while an MOS type transistor in a memory cell region is in a floating state and an MOS type transistor in a region other than the memory cell region is in a non-floating state in the structure, a film thickness of the semiconductor layer comprising body regions of both MOS type transistors is uniform to make the surface of the semiconductor substrate flat. Thus, an objective of the present invention is to provide, by avoiding the above manufacturing problems, a structure on an SOI type substrate in which only a memory cell region is a transistor in a floating state and a process for readily manufacturing the structure. A major objective of the present invention is to allow for readily manufacturing a DRAM with a higher integration degree by permitting further size reduction by eliminating a capacitor part which is unworkable during production.

### SUMMARY OF THE INVENTION

An embodiment of the present invention relates to a semiconductor memory device, comprising:

(1) an SOI type substrate in which a semiconductor substrate, an insulating layer and a semiconductor layer are laminated in order;

(2) a first region comprising
(i) an isolation region A formed extending from the surface of the semiconductor layer to the insulating layer in a thickness direction, and
(ii) an MOS type transistor A, comprising
   a semiconductor region A formed within the semiconductor layer which is insulated and isolated by the isolation region A,
   a gate electrode A formed over the semiconductor region A, and
   a source region A/ a drain region A formed in both sides sandwiching the gate electrode A within the semiconductor region A, wherein the source region A/ the drain region A extends from the surface of the semiconductor region A to the insulating layer in a thickness direction; and

(3) a second region comprising
(i) an isolation region B formed extending from the surface of the semiconductor layer to a depth not reaching the insulating layer in a thickness direction, and
(ii) an MOS type transistor B, comprising
   a semiconductor region B formed within the semiconductor layer which is insulated and isolated by the isolation region B,
   a gate electrode B formed over the semiconductor region B, and
   a source region B/ a drain region B formed in both sides sandwiching the gate electrode B within the semiconductor region B, wherein the source region B/ the drain region B extends from the surface of the semiconductor region B to a depth not reaching the insulating layer in a thickness direction.

Another embodiment of the present invention relates to a semiconductor memory device, comprising:

(1) an SOI type substrate in which a semiconductor substrate, an insulating layer and a semiconductor layer are laminated in order;

(2) a first region comprising
(i) an isolation region A formed by filling a trench A penetrating the semiconductor layer to the insulating layer in a thickness direction, with an insulating material, and
(ii) an MOS type transistor A, comprising
   a semiconductor region A formed within the semiconductor layer which is insulated and isolated by the isolation region A,
   a gate electrode A formed over the semiconductor region A, and
   a source region A/drain region A formed in both sides sandwiching the gate electrode A within the semiconductor region A, wherein the source region A/drain region A extends over the whole length in a thickness direction of the semiconductor region A and whose bottom is contact with the insulating layer; and

(3) a second region comprising
(i) an isolation region B formed by filling a trench B extending from the surface of the semiconductor layer to a depth not reaching the insulating layer in a thickness direction, with an insulating material, and
(ii) an MOS type transistor B, comprising
   a semiconductor region B formed within the semiconductor layer which is insulated and isolated by the isolation region B,
   a gate electrode B formed over the semiconductor region B, and
   a source region B/ a drain region B formed in both sides sandwiching the gate electrode B within the semiconductor region B, wherein the bottom of the source region B/ the drain region B does not reach the insulating layer.

Another embodiment of the present invention relates to a process for manufacturing a semiconductor memory device comprising an SOI type substrate where a semiconductor substrate, an insulating layer and a semiconductor layer are laminated in order, comprising:

preparing the SOI type substrate;

forming an isolation region A extending within the semiconductor layer from the surface of the semiconductor layer to the insulating layer in a thickness direction and an isolation region B extending within the semiconductor layer from the surface of the semiconductor layer to a depth not reaching the insulating layer in a thickness direction;

forming, within a semiconductor region A which is insulated and isolated by the isolation region A within the semiconductor layer, an MOS type transistor A comprising a source region A/a drain region A extending from the surface of the semiconductor region A to the insulating film in a thickness direction; and

forming, within a semiconductor region B which is insulated and isolated by the isolation region B within the semiconductor layer, an MOS type transistor B comprising a source region B/a drain region B extending from the surface of the semiconductor region B to a depth not reaching the insulating layer in a thickness direction.

A semiconductor memory device of the present invention has a structure where an STI for isolation (isolation region A) in a memory cell region (first region) and a diffusion layer for a source region A/a drain region A in an MOS type transistor A extend from the surface of a semiconductor layer within an SOI type substrate to an insulating layer in a thickness direction. Thus, a body region (a region where a channel is to be formed) in a transistor in the memory cell region is in a floating state, allowing for capacitorless information storage utilizing hole accumulation effect.

On the other hand, a peripheral circuit region (second region) other than the memory cell region has a structure where both STI for isolation (isolation region B) and diffusion layer for a source region B/a drain region B in an MOS type transistor B extend from the surface of a semiconductor layer within the SOI type substrate to a depth not reaching the insulating layer in a thickness direction. In such a structure, the transistor in the peripheral circuit region can have fixed potentials of a body region and a well region, resulting in stable circuit operation without variation of a transistor threshold voltage.

In a semiconductor memory device of the present invention, while in the memory cell region and the peripheral circuit region an STI for isolation and an MOS type transistor have the above structure, the silicon layer in the surface of the SOI type substrate has an equal thickness in both the memory cell region and the periphery circuit region. Thus, the surface of the SOI type substrate is so flat that processings such as patterning using a photoresist film and removing a layer using CMP can be facilitated. It, therefore, allows a high-performance and highly integrated capacitorless DRAM to be easily formed.

### BRIEF DESCRIPTION OF THE DRAWINGS

FIG. 1 is a cross-sectional view showing a related semiconductor memory device.

FIG. 2 is a plan view showing a related semiconductor memory device.

FIG. 3 is a cross-sectional view showing an example of a semiconductor memory device according to the present invention.

FIG. 4 is a cross-sectional view showing an example of a semiconductor memory device according to the present invention.

FIG. 5 is a cross-sectional view showing an example of a semiconductor memory device according to the present invention.

FIG. 6 is a cross-sectional view showing an example of a semiconductor memory device according to the present invention.

FIG. 7 is a cross-sectional view showing an example of a semiconductor memory device according to the present invention.

FIG. 8 is a cross-sectional view showing a part of an exemplary manufacturing process for a semiconductor memory device according to the present invention.

FIG. 9 is a cross-sectional view showing a part of an exemplary manufacturing process for a semiconductor memory device according to the present invention.

FIG. 10 is a cross-sectional view showing a part of an exemplary manufacturing process for a semiconductor memory device according to the present invention.

FIG. 11 is a cross-sectional view showing a part of an exemplary manufacturing process for a semiconductor memory device according to the present invention.

FIG. 12 is a cross-sectional view showing a part of an exemplary manufacturing process for a semiconductor memory device according to the present invention.

FIG. 13 is a cross-sectional view showing a part of an exemplary manufacturing process for a semiconductor memory device according to the present invention.

FIG. 14 is a cross-sectional view showing a part of an exemplary manufacturing process for a semiconductor memory device according to the present invention.

FIG. 15 is a cross-sectional view showing a part of an exemplary manufacturing process for a semiconductor memory device according to the present invention.

FIG. 16 is a cross-sectional view showing a part of an exemplary manufacturing process for a semiconductor memory device according to the present invention.

FIG. 17 is a cross-sectional view showing a part of an exemplary manufacturing process for a semiconductor memory device according to the present invention.

FIG. 18 is a cross-sectional view showing a part of an exemplary manufacturing process for a semiconductor memory device according to the present invention.

FIG. 19 is a cross-sectional view showing a part of an exemplary manufacturing process for a semiconductor memory device according to the present invention.

FIG. 20 is a cross-sectional view showing a part of an exemplary manufacturing process for a semiconductor memory device according to the present invention.

FIG. 21 is a cross-sectional view showing a part of an exemplary manufacturing process for a semiconductor memory device according to the present invention.

FIG. 22 is a cross-sectional view showing a part of an exemplary manufacturing process for a semiconductor memory device according to the present invention.

FIG. 23 is a cross-sectional view showing a part of an exemplary manufacturing process for a semiconductor memory device according to the present invention.

FIG. 24 is a cross-sectional view showing a part of an exemplary manufacturing process for a semiconductor memory device according to the present invention.

FIG. 25 is a cross-sectional view showing a part of an exemplary manufacturing process for a semiconductor memory device according to the present invention.

FIG. 26 is a cross-sectional view showing a part of an exemplary manufacturing process for a semiconductor memory device according to the present invention.

FIG. 27 is a cross-sectional view showing a part of an exemplary manufacturing process for a semiconductor memory device according to the present invention.

FIG. 28 is a cross-sectional view showing a part of an exemplary manufacturing process for a semiconductor memory device according to the present invention.

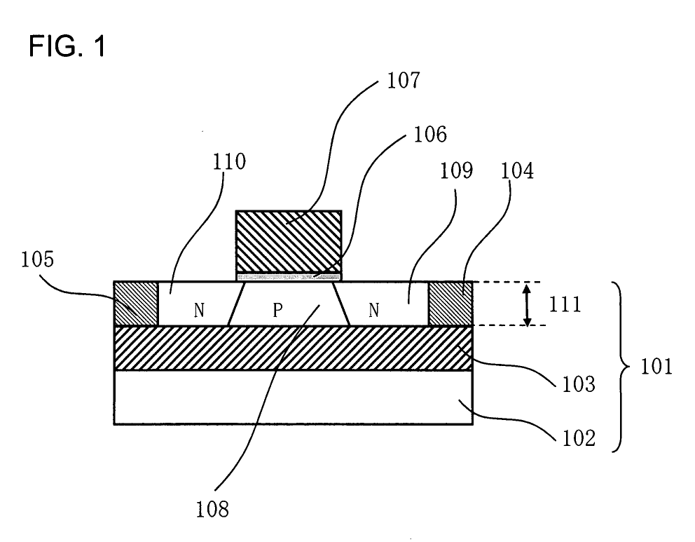

In the drawings, the symbols have the following meanings; 101: SOI type substrate, 102: silicon substrate, 103: silicon oxide layer, 104: silicon oxide film for isolation, 105: silicon oxide film for isolation, 106: gate insulating film, 107: gate electrode, 108: body region, 109, 110: source region/drain region, 111: silicon layer, 120: isolation region, 121: contact plug, 122: dopant diffusion layer region, 123: gate electrode (word line), 124: bit line, 130: memory cell region, 131: periphery circuit region, 132: isolation region, 133: N-type dopant diffusion layer region, 134: gate electrode, 140: N-channel type MOS transistor region, 141: P-channel type MOS transistor region, 142: N-type well, 143: isolation region, 144: gate electrode, 145: P-type dopant diffusion layer region, 146: N-type dopant diffusion layer region, 147: N-type dopant diffusion layer region, 151: SOI type substrate, 152: silicon substrate, 153: silicon oxide layer for insulation, 154: upper silicon layer, 155: gate insulating film, 156: gate electrode, 157: first N-type diffusion layer region, 158: second N-type diffusion layer region, 159: P-type diffusion layer region, 160: isolation region, 170: N-type well, 171: P-type well, 172: isolation region, 173: P-type diffusion layer region, 174: N-type diffusion layer region, 180: N-type diffusion layer region, 181: photoresist film, 182: photoresist film, 190: photoresist film, 191: first N-type diffusion layer region, 192: second N-type diffusion layer region, 193: photoresist film, 195: N-type diffusion layer region, 196: P-type diffusion layer region, 198: N-type diffusion layer region, 201: SOI type substrate, 202: lowermost silicon substrate, 203: silicon oxide layer for insulation, 204: upper silicon layer, 205: silicon oxide film, 206: silicon nitride film, 207: first hole, 208: silicon oxide film, 209: silicon nitride film, 210: second hole, 211: second isolation region, 220: trench for an isolation region, 221: trench for an isolation region, 222: photoresist film, 223: deep isolation region, 224: shallow isolation region, 225: region comprising oxygen-implanted silicon layer, 226: silicon oxide film, 227: silicon oxide film, 228: deep isolation region, and 229: shallow isolation region.

### DETAILED DESCRIPTION OF PREFERRED EMBODIMENTS

### 1. Semiconductor Memory Device

A first semiconductor memory device comprises the following parts.

(1) An SOI type substrate is formed by laminating a semiconductor substrate, an insulating layer and a semiconductor layer in order.

(2) The first region comprises the following (i) and (ii).
(i) an isolation region A formed extending from the surface of the semiconductor layer to the insulating layer in a thickness direction
(ii) an MOS type transistor A comprising
   a semiconductor region A formed within the semiconductor layer which is insulated and isolated by the isolation region A,
   a gate electrode A formed over the semiconductor region A, and
   a source region A/ a drain region A formed in both sides sandwiching the gate electrode A within the semiconductor region A, wherein the source region A/ the drain region A extends from the surface of the semiconductor region A to the insulating layer in a thickness direction

(3) The second region comprises the following (i) and (ii).
(i) an isolation region B formed extending from the surface of the semiconductor layer to a depth not reaching the insulating layer in a thickness direction
(ii) an MOS type transistor B comprising
   a semiconductor region B formed within the semiconductor layer which is insulated and isolated by the isolation region B,
   a gate electrode B formed over the semiconductor region B, and
   a source region B/ a drain region B formed in both sides sandwiching the gate electrode B within the semiconductor region B, wherein the source region B/ the drain region B extends from the surface of the semiconductor region B to a depth not reaching the insulating layer in a thickness direction.

A second semiconductor memory device comprises the following parts.

(1) An SOI type substrate is formed by laminating a semiconductor substrate, an insulating layer and a semiconductor layer in order.

(2) The first region comprises the following (i) and (ii).
(i) an isolation region A formed by filling a trench A penetrating the semiconductor layer to the insulating layer in a thickness direction, with an insulating material
(ii) an MOS type transistor A comprising
   a semiconductor region A formed within the semiconductor layer which is insulated and isolated by the isolation region A,
   a gate electrode A formed over the semiconductor region A, and
   a source region A/drain region A formed in both sides sandwiching the gate electrode A within the semiconductor region A, wherein the source region A/drain region A extends over the whole length in a thickness direction of the semiconductor region A and whose bottom is contact with the insulating layer

(3) The second region comprises the following (i) and (ii).
(i) an isolation region B formed by filling a trench B extending from the surface of the semiconductor layer to a depth not reaching the insulating layer in a thickness direction, with an insulating material
(ii) an MOS type transistor B comprising
   a semiconductor region B formed within the semiconductor layer which is insulated and isolated by the isolation region B,
   a gate electrode B formed over the semiconductor region B, and
   a source region B/ a drain region B formed in both sides sandwiching the gate electrode B within the semiconductor region B, wherein the bottom of the source region B/ the drain region B does not reach the insulating layer

Thus, the first and the second semiconductor memory devices have a structure where both isolation region A and source region A/drain region A within the memory cell region (first region) extend from the surface of the semiconductor layer to the insulating layer in a thickness direction (a structure where they are formed over the whole length of the semiconductor layer in the thickness direction; a structure where they are continuously formed from the surface side of the semiconductor layer to the side of the insulating layer). The periphery circuit region (second region) has a structure where both isolation region B and source region B/drain region B extend from the surface of the semiconductor layer to a depth not reaching the insulating layer in a thickness direction (a structure where in terms of a thickness direction of the semiconductor layer, they are partially formed from the surface of the semiconductor layer; a structure where they are continuously formed from the surface of the semiconductor layer to a halfway within the semiconductor layer in a thickness direction).

Herein, the surfaces of the semiconductor layer, the semiconductor region A and the semiconductor region B refer to the surfaces opposite to the side of the insulating layer (the surface in the side where the gate electrodes A and B are formed).

In the first and the second semiconductor memory devices, as described above, the body region (a region where a channel is formed) of the transistor in the memory cell region is in a floating state, and hole accumulation effect can be utilized to perform capacitorless information storage. Furthermore, the transistor in the periphery circuit region can fix potentials in the body region and the well region, allowing a circuit to stably operate without variation in a transistor threshold voltage. Furthermore, a film thickness of the semiconductor layer in the surface of the SOI type substrate is equal in the memory cell region and the periphery circuit region. Thus, the surface of the SOI type substrate is so flat to facilitate processings such as patterning using a photoresist film and polishing using CMP. Thus, a high-performance and highly integrated capacitorless DRAM can be easily formed.

The first and the second regions comprise the semiconductor region A and the semiconductor region B, respectively. This semiconductor region A is insulated and isolated by the isolation region A while being surrounded by the isolation region A and the insulating layer. Thus, a region where a channel of an MOS type transistor A is to be formed can be electrically in a floating state. The semiconductor region B is insulated and isolated by the isolation region B, but incompletely surrounded by the isolation region B and, the insulating layer. Therefore, the MOS type transistor B can fix a potential of a region where its channel is to be formed.

In the first and the second semiconductor memory devices, the gate electrodes A and B are formed on the semiconductor regions A and B, respectively. In addition, gate insulating films are formed between the semiconductor region A and the gate electrode A and between the semiconductor region B and the gate electrode B, respectively. Furthermore, in both sides sandwiching the gate electrode A within the semiconductor region A, the source region A/the drain region A are formed, extending from the surface of the semiconductor region A to the insulating layer in a thickness direction. Furthermore, in both sides sandwiching the gate electrode B within the semiconductor region B, the source region B/the drain region B are formed, extending from the surface of the semiconductor region B to a depth not reaching the insulating layer in a thickness direction.

It is preferable that the source region A/the drain region A comprise a first diffusion layer formed in the surface side of the semiconductor layer and a second diffusion layer formed in the side of the insulating layer under the first diffusion layer. Typically, a dopant contained in the first diffusion layer is different from a dopant contained in the second diffusion layer. Furthermore, it is preferable that a dopant concentration is different between the first diffusion layer and the second diffusion layer and that a dopant concentration of the first diffusion layer is higher than that of the second diffusion layer. Thus, an appropriate potential can be applied to the gate electrode A, to reduce a leak current. In addition, a time for refreshing stored data can be increased.

The first and the second regions comprise the MOS type transistors A and B, respectively. There may be one or two or more of these MOS type transistors A and B in the first and the second regions, respectively. The MOS type transistors A and B may be an N-channel type MOS transistor, a P-channel type MOS transistor or a combination of these MOS type transistors. Preferably, the first region comprises an N-channel type MOS transistor as the MOS type transistor A and the second region comprises an N-channel type and a P-channel type MOS transistors as the MOS type transistor B. The MOS type transistors A and B comprising such configurations can allow for a semiconductor memory device which has an excellent storage capacity and ensures more stable operation.

A memory cell region in a semiconductor memory device of the present invention can store information as described below.

### Operation Method

In the first and the second semiconductor memory devices, the MOS type transistor A contained in the first region can have at least two threshold-voltage states. Specifically, referring to a case where the MOS type transistor A is an N-channel type MOS transistor, first, while the source region A is at a ground potential (GND potential), a positive voltage is applied the drain region A and the gate electrode A to make the transistor ON for applying a large current. Here, the current causes impact ionization near the drain region A, so that holes as a majority carrier in the body region are accumulated in the body region. Then, by applying an appropriate voltage to the gate electrode A and the drain region A, the state of hole accumulation can be held for a certain period.

When holes are thus accumulated within the body region, substrate bias effect causes variation in a threshold voltage of the transistor in comparison with that when no holes are accumulated. That is, in the state of hole accumulation, a threshold voltage is lower than that in the state of no accumulation. The accumulated holes can be discharged to the exterior by applying a negative voltage to the drain region A. Then, by defining a threshold voltage of the state without hole accumulation as a “0” state and a threshold voltage of the state with hole accumulation as a “1” state, it can be functioned as a memory having one bit information.

As described above, when reading the information stored in the memory cell, while a voltage applied to the gate electrode A and the drain region A is adjusted to keeping a small current such that new impact ionization does not occur, the state “0” or “1” can be detected by determining a level of a threshold voltage.

The MOS type transistor A contained in the first region preferably has a structure where one MOS type transistor A has a plurality of mutually different threshold voltage states and the states can be retained for a given period.

Although the isolation region is typically made of silicon oxide, there are no particular restrictions to the material as long as it is an insulating material. Furthermore, the semiconductor layer is preferably a silicon semiconductor.

Examples of a semiconductor memory device of the present invention will be detailed with reference to the drawings.

### Example 1

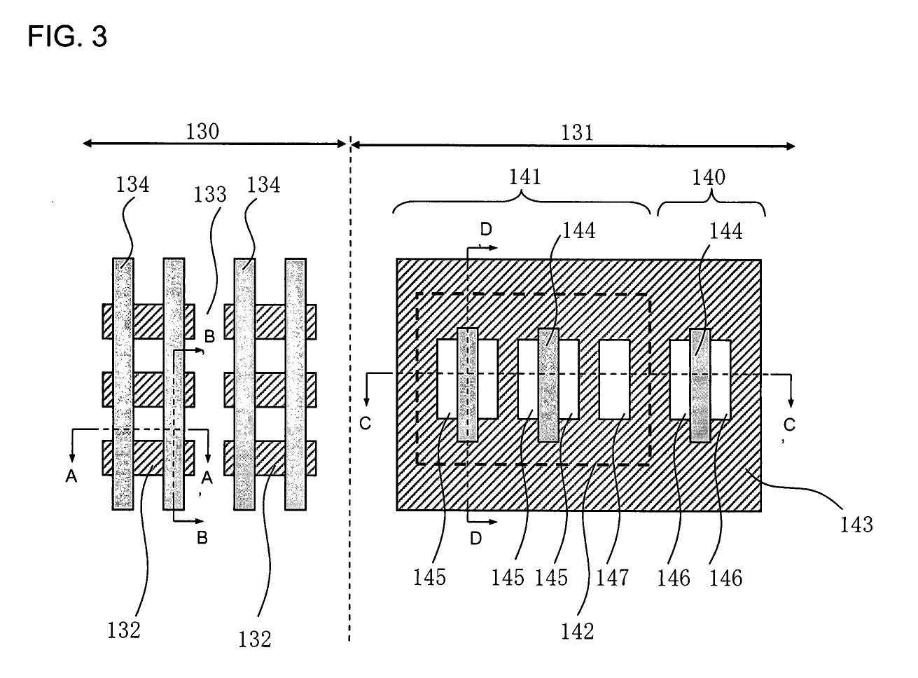

FIG. 3 is a plan view showing Example 1, that is, a view schematically illustrating transistors in a memory cell region (a first region) and in a periphery circuit region other than the memory cell (a secondary region).

In this figure, 130 is a memory cell region, and 131 is a periphery circuit region, and both are formed on an SOI type substrate (not shown). Within the memory cell region 130, isolation regions A 132 formed by STI (Shallow Trench Isolation) are regularly disposed. Here, 133 is an N-type dopant diffusion layer region defined as a lattice by the isolation regions A 132. And, 134 is a gate electrode A, which operates as a word line for a DRAM element.

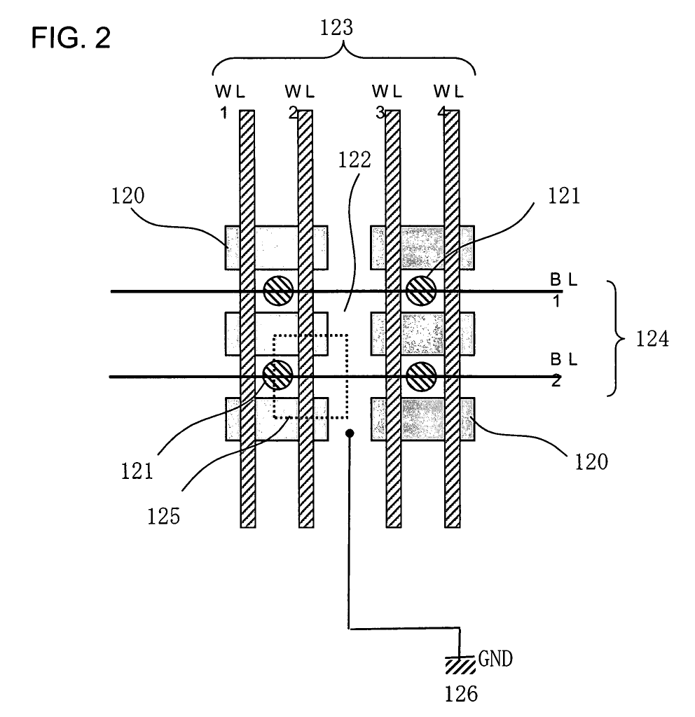

In FIG. 3, for simplicity, bit lines are not shown, but in a practical memory cell, they are disposed in a direction perpendicular to the word lines as shown in FIG. 2. A transistor in the memory cell region 130 is an N-channel type MOS transistor A, which has a floating body structure.

In the periphery circuit region 131, 140 and 141 are formed as an N-channel type MOS transistor B region and a P-channel type MOS transistor region B, respectively, for making up a CMOS circuit. In the periphery circuit region 131, 142 is an N-type well while the region other than an N-type well is a P-type well. In addition, 143 is an isolation region B formed using STI. Furthermore, 144 is a gate electrode B, which is made up of the same interconnection layer as that in the gate electrode A 134 within memory cell region 130.

In the periphery circuit region 131, 145 is a P-type dopant diffusion layer region, which operates as a source region B/a drain region B in the P-channel type MOS transistor B. Furthermore, 146 is an N-type dopant diffusion layer region, which operates as a source region B/a drain region B in the N-channel type MOS transistor B. In addition, 147 is an N-type dopant diffusion layer region, which is used for drawing an interconnection for fixing a potential of the N-type well 142.

FIG. 3, for simplified explanation, does not show a contact hole or an upper interconnection layer which are formed in the manufacturing steps after forming the gate electrode.

Furthermore, in the following description, an N-type dopant diffusion layer region is appropriately referred to as an N-type diffusion layer region for simple expression. Similarly, a P-type dopant diffusion layer region is appropriately referred to as a P-type diffusion layer region.

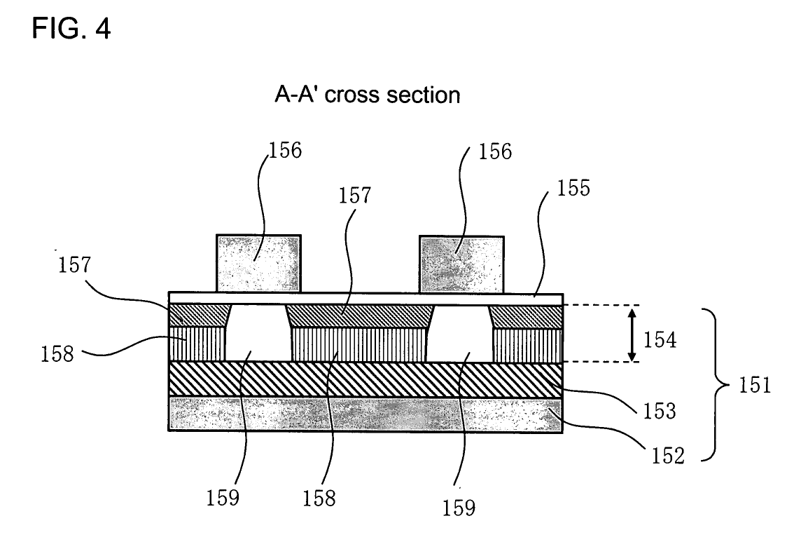

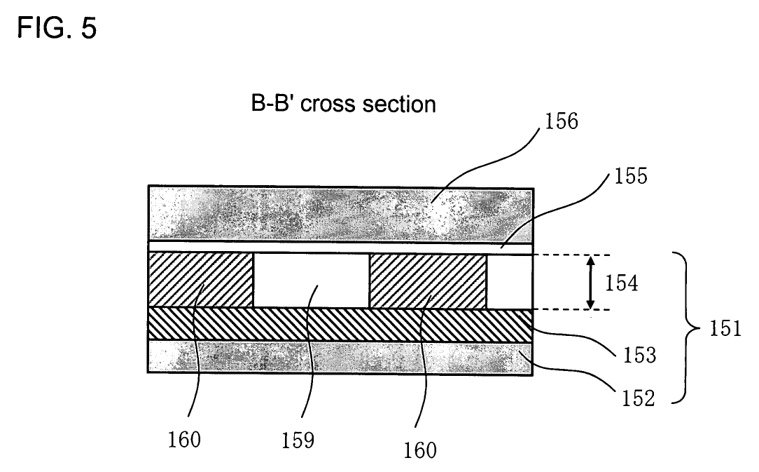

FIGS. 4 and 5 are cross-sectional views of the memory cell region 130 taken on lines A-A′ and B-B′ of FIG. 3, respectively.

In FIG. 4, 151 is an SOI type substrate, consisting of three layers, that is, a silicon substrate (semiconductor substrate) 152 as a base for supporting, a silicon oxide layer for insulation (insulating layer) 153 on the silicon substrate and an upper silicon layer (semiconductor layer) 154 on the silicon oxide layer. The semiconductor device of this example is formed using the part of the upper silicon layer 154.

Furthermore, 155 is a gate insulating film and 156 is a gate electrode A. This gate electrode A 156 operates as a word line for a DRAM element. In FIG. 4, 157 is a first N-type diffusion layer region and 158 is a second N-type diffusion layer region. The upper part of the second N-type diffusion layer region 158 is in contact with the bottom of the first N-type diffusion layer region 157, and the bottom of the second N-type diffusion layer region 158 is in contact with the silicon oxide layer 153 in the SOI type substrate. The upper part of the first N-type diffusion layer region 157 is the surface of the silicon layer 154, which is in contact with the gate insulating film 155. Furthermore, immediately beneath this gate electrode A 156, there is a P-type diffusion layer region 159, which operates as a body region of the transistor.

In FIG. 5, the same components as those in FIG. 4 are denoted by the same numbers. In FIG. 5, 151 is an SOI type substrate consisting of three layers, that is, a silicon substrate (semiconductor substrate) 152 as a base for supporting, a silicon oxide layer for insulation (insulating layer) 153 on the silicon substrate and an upper silicon layer (semiconductor layer) 154 on the silicon oxide layer. Furthermore, 155 is a gate insulating film and 156 is a gate electrode A. In addition, 160 is an isolation region A formed using STI, whose bottom is in contact with the silicon oxide layer 153 in the SOI type substrate. Furthermore, 159 is a P-type diffusion layer region formed immediately beneath the gate electrode A of the transistor.

As shown in FIGS. 3 to 5, the periphery of the P-type diffusion layer region 159 which operates as a body region in the transistor contained in the memory cell region is surrounded by the first and the second N-type diffusion layer regions 157 and 158 as shown in FIG. 4 and the isolation region 160 as shown in FIG. 5. Furthermore, the bottom of the P-type diffusion layer region 159 is insulated by the silicon oxide layer 153 in the SOI type substrate. Therefore, in the state where a reverse bias of PN-junction is applied between the first and the second N-type diffusion layer regions 157 and 158 and the P-type diffusion layer region 159, the P-type diffusion layer region 159 can be maintained in an electrically floating state. In other words, the transistor constituting the memory cell operates as a floating-body type transistor.

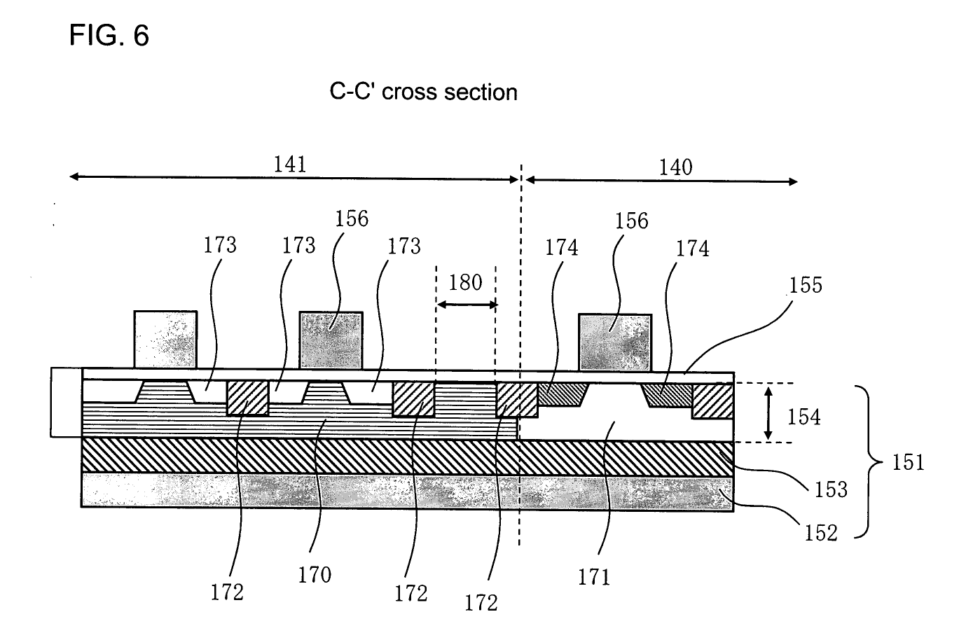

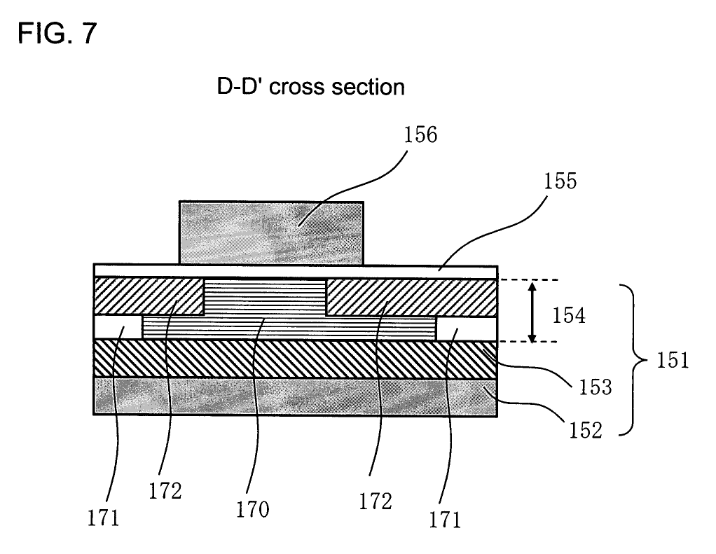

Next, FIGS. 6 and 7 are cross-sectional views of the periphery circuit region 131 taken on lines C-C′ and D-D′ of FIG. 3, respectively. In FIG. 6, the same components as those in FIG. 4 are denoted by the same numbers. In FIG. 6, 151 is an SOI type substrate consisting of three layers, that is, a silicon substrate 152 as a base for supporting, a silicon oxide layer for insulation 153 on the silicon substrate and an upper silicon layer 154 on the silicon oxide layer.

In this example, the upper silicon layer 154 in the SOI type substrate has an equal film thickness in the memory cell region 130 and the periphery circuit region 131 in FIG. 3. Within the silicon layer 154 in this SOI type substrate, a n N-type well 170 and a P-type well 171 are formed. The bottoms of both N-type well 170 and P-type well 171 are in contact with the silicon oxide layer 153 in the SOI type substrate.

The region where the N-type well 170 is formed operates as a P-channel type MOS transistor region B 141 (FIG. 3). The region where the P-type well 171 is formed operates as an N-channel type MOS transistor region B 140 (FIG. 3). Furthermore, 155 is a gate insulating film and 156 is a gate electrode B.

Here, 172 is an isolation region B formed using STI, whose bottom does not reach the silicon oxide layer 153 in the SOI type substrate unlike the isolation region A 160 in the memory cell region shown in FIG. 5. Furthermore, 173 is a P-type diffusion layer region, which operates as a source region B/a drain region B in the P-channel type MOS transistor B. The bottom of the P-type diffusion layer region 173 does not also reach the silicon oxide layer 153 in the SOI type substrate.

Here, 174 is an N-type diffusion layer region which operates as a source region B/a drain region B in the N-channel type MOS transistor B. The bottom of the N-type diffusion layer region 174 does not also reach the silicon oxide layer 153 in the SOI type substrate.

In FIG. 6, 180 is an N-type diffusion layer region for fixing a potential of the N-type well 170. A desired potential may be applied to the N-type diffusion layer region 180 by connecting the N-type diffusion layer region 180 with an interconnection (not shown) for drawing. In FIG. 6, although the N-type diffusion layer region 180 uses the surface region of the N-type well 170 as it is, as a diffusion layer, an N-type dopant can be ion-implanted to the N-type diffusion layer region 180 for reducing a contact resistance between the interconnection for drawing and the N-type well 170, to form a high-concentration N-type diffusion layer. Although not shown in FIG. 6, in the P-type well 171, a potential can be also fixed by forming a P-type diffusion layer region for potential fixing, like the N-type well 170.

In FIG. 7, the same components as those in FIGS. 4 and 6 are denoted by the same numbers. In FIG. 7, 151 is an SOI type substrate consisting of three layers, that is, a silicon substrate 152 as a base for supporting, a silicon oxide layer for insulation 153 on the silicon substrate and an upper silicon layer 154 on the silicon oxide layer. Here, 170 is an N-type well, 171 is a P-type well, 155 is a gate insulating film and 156 is a gate electrode B. Furthermore, 172 is an isolation region B formed by using STI, whose bottom does not reach the silicon oxide layer 153 in the SOI type substrate.

As shown in FIGS. 6 and 7, in the transistor which is formed in the periphery circuit region, the isolation region B 172, the P-type diffusion layer region 173 and the N-type diffusion layer region 174 do not reach the silicon oxide layer 153 which is an insulating layer in the SOI type substrate. Thus, it has a configuration equivalent to an MOS type transistor formed in a common semiconductor substrate without an SOI structure (a semiconductor substrate made of a silicon monolayer). That is, a region where a channel for a transistor (a body region) is not in a floating state, and is fixed to a potential of the N-type well 170 or the P-type well 171.

As obvious from the description of FIGS. 3 to 7, in a semiconductor memory device of the present invention, a transistor in a memory cell region has a body region in a floating state while a transistor in a region other than the memory cell region (a periphery circuit region) is not in a floating state.

### 2. Manufacturing Process for a Semiconductor Memory Device

A process for manufacturing a semiconductor device of the present invention has the following steps.

preparing the SOI type substrate,

forming an isolation region A extending within the semiconductor layer from the surface of the semiconductor layer to the insulating layer in a thickness direction and an isolation region B extending within the semiconductor layer from the surface of the semiconductor layer to a depth not reaching the insulating layer in a thickness direction,

forming, within a semiconductor region A which is insulated and isolated by the isolation region A within the semiconductor layer, an MOS type transistor A comprising a source region A/a drain region A extending from the surface of the semiconductor region A to the insulating film in a thickness direction, and

forming, within a semiconductor region B which is insulated and isolated by the isolation region B within the semiconductor layer, an MOS type transistor B comprising a source region B/a drain region B extending from the surface of the semiconductor region B to a depth not reaching the insulating layer in a thickness direction.

The step of forming the isolation region A and the isolation region B may be, for example, any of the following processes (a) to (c).

(a) a process comprising the steps of:

forming trench A having a depth penetrating the semiconductor layer in a thickness direction from the surface of semiconductor layer to the insulating layer,

forming trench B extending from the surface of the semiconductor layer to a depth not reaching the insulating layer in a thickness direction, and

filling trench A and trench B with an insulating material.

(b) a process comprising the steps of:

forming a hole and trench B extending from the surface of the semiconductor layer to a depth not reaching the insulating layer in a thickness direction,

extending the hole in the semiconductor layer in a thickness direction to form trench A having a depth reaching the insulating layer, and

filling trench A and trench B with an insulating material.

(c) a process comprising the steps of:

forming trench A and trench B extending from the surface of the semiconductor layer to a depth not reaching the insulating layer in a thickness direction,

introducing oxygen atoms into region C in the semiconductor layer, from the bottom of trench A to the insulating layer in a thickness direction,

thermally oxidizing the semiconductor layer under a high-temperature oxidizing atmosphere to convert region C into an insulator and forming an oxide film in the inner walls of trench A and trench B, and

filling trench A and trench B with an insulating material.

In the step of “filling trench A and trench B with an insulating material” in the above processes (a) to (c), trench A and trench B may be separately or simultaneously filled with an insulating material.

### Example 1

There will be described a process for manufacturing Example 1 with reference to the drawings.

First, before describing all the steps in the manufacturing process for a semiconductor memory device of this example, there will be described a process for forming isolation regions having different depths (when using process (a) as the step of forming the isolation region A and the isolation region B).

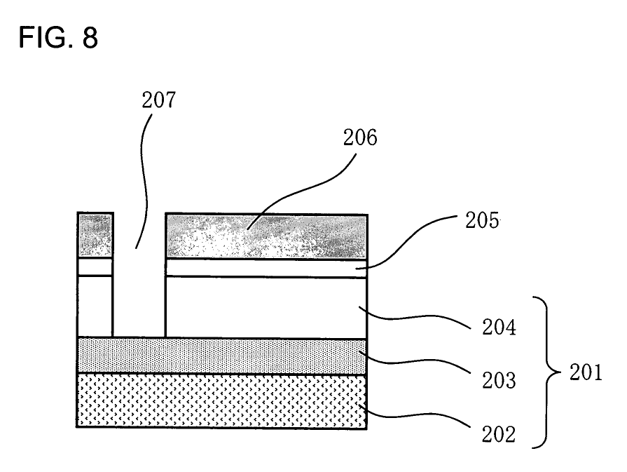

FIGS. 8 to 13 are cross-sectional views of individual manufacturing steps, showing a process for forming isolation regions having different depths in the same semiconductor chip. In FIG. 8, 201 is an SOI type substrate consisting of three layers, that is, a lowermost silicon substrate (semiconductor substrate) 202, a silicon oxide layer (SiO₂) 203 as an insulating layer and an upper silicon layer (semiconductor layer) 204.

First, a silicon oxide film 205 and a silicon nitride film (Si₃N₄) 206 were formed on the upper silicon layer 204 of the SOI type substrate. Then, patterning was conducted by dry etching using a photoresist film (not shown) as a mask, for etching the silicon nitride film 206, the silicon oxide film 205 and the upper silicon layer 204 to form a first hole (trench A) 207. Here, in the first hole 207, the silicon layer was etched until the upper silicon layer 204 was completely removed, to expose the surface of the silicon oxide layer 203.

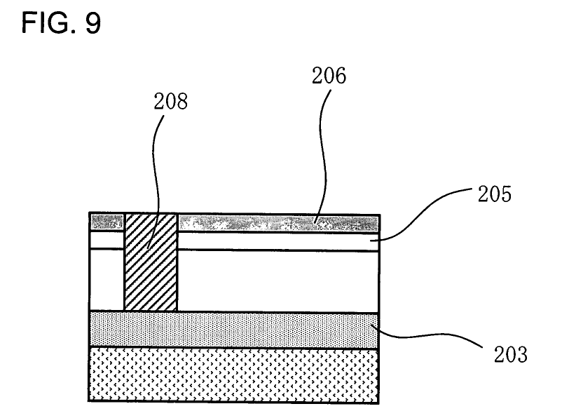

Then, a silicon oxide film was deposited by CVD such that it filled the first hole 207. Then, as shown in FIG. 9, the silicon oxide film on the surface of the silicon nitride film 206 was removed by CMP such that the silicon oxide film (insulating material) 208 was left only for the first hole. The silicon oxide film 208 thus formed operates as a first isolation region A (208). Since the surface of the silicon nitride film 206 is partly removed when removing the silicon oxide film by CMP, a film thickness of the silicon nitride film 206 was adjusted during first forming the silicon nitride film 206 for leaving the silicon nitride film 206 at the end of CMP.

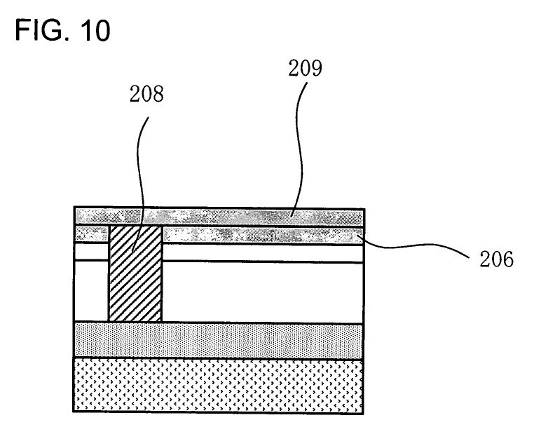

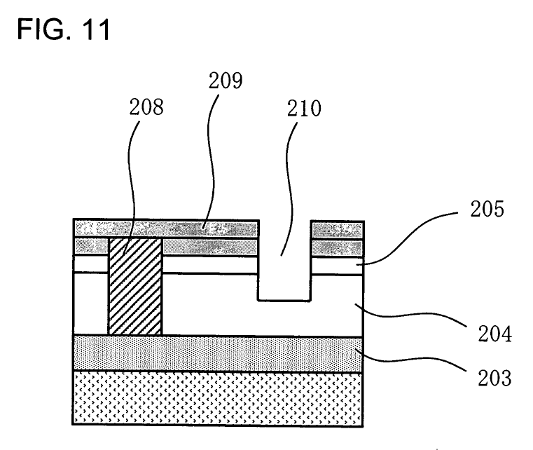

Subsequently, as shown in FIG. 10, a new silicon nitride film 209 was formed to cover the surface of the first isolation region A 208. Next, as shown in FIG. 11, patterning was conducted using a photoresist film (not shown), to form a second hole (trench B) 210. Here, in the second hole 210, the etching amount of silicon was adjusted such that there was formed a hole extending to the middle of the film thickness of the upper silicon layer 204.

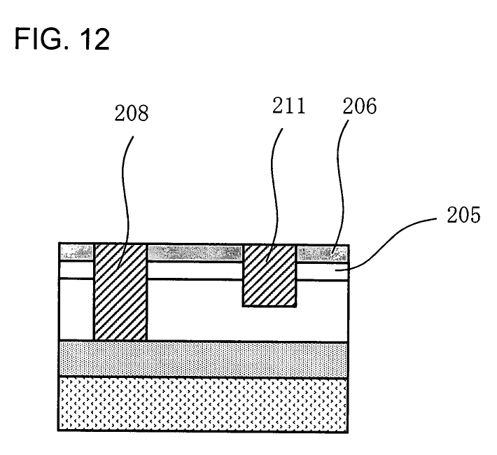

Next, a silicon oxide film (insulating material) was deposited by CVD such that it filled the second hole 210. Then, as shown in FIG. 12, the silicon oxide film and the silicon nitride film 209 on the substrate surface were removed by CVD, to form a second isolation region B 211. It is of no matter that CMP polishes somewhat the surface of the silicon nitride film 206 and the surface of the first isolation region A 208. Furthermore, as shown in FIG. 12, the surface of the first isolation region A 208 is at the same level as the surface of the second isolation region B 211 after CMP.

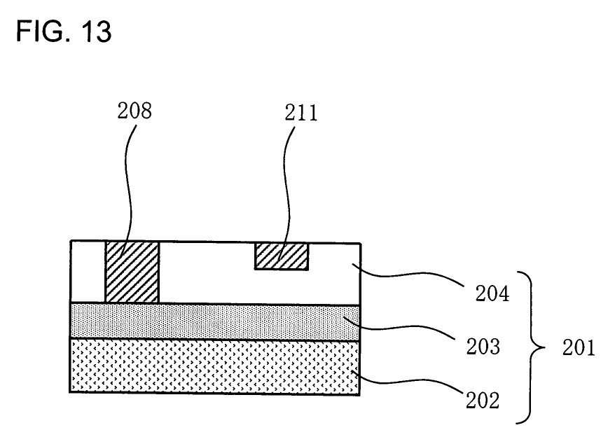

Then, the silicon nitride film 206 was removed by wet etching. Subsequently, wet etching was conducted to remove the surfaces of the silicon oxide film 205 and the first isolation region A 208, and the second isolation region B 211. As a result, as shown in FIG. 13, the isolation region A 208 and the isolation region B 211 having different depths could be formed. The first isolation region A 208 penetrates the upper silicon layer 204, and the bottom of the first isolation region A 208 is in contact with the silicon oxide layer 203 which is the insulating layer in the SOI type substrate 201. On the other hand, the second isolation region B 211 does not penetrate the upper silicon layer 204, and the bottom of the first isolation region B 211 is not in contact with the silicon oxide layer 203.

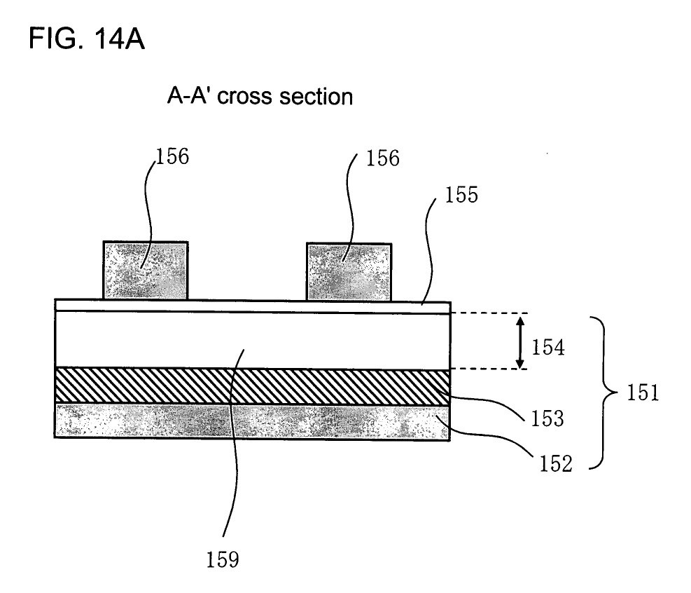

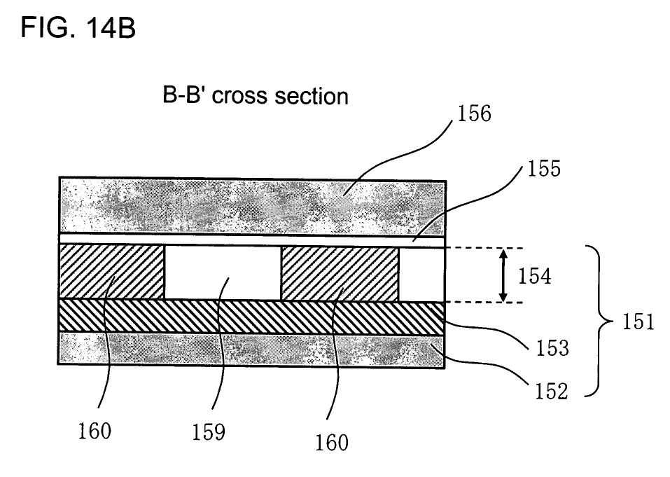

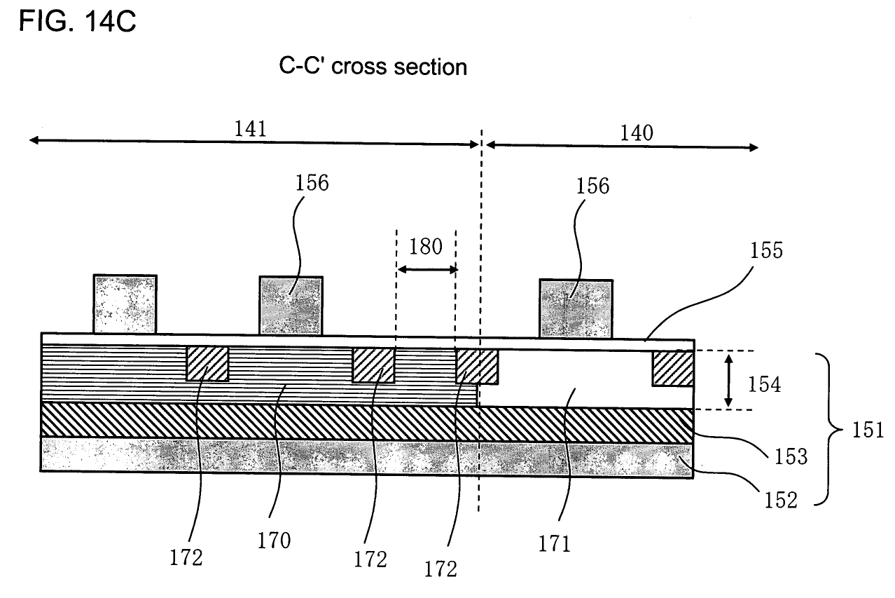

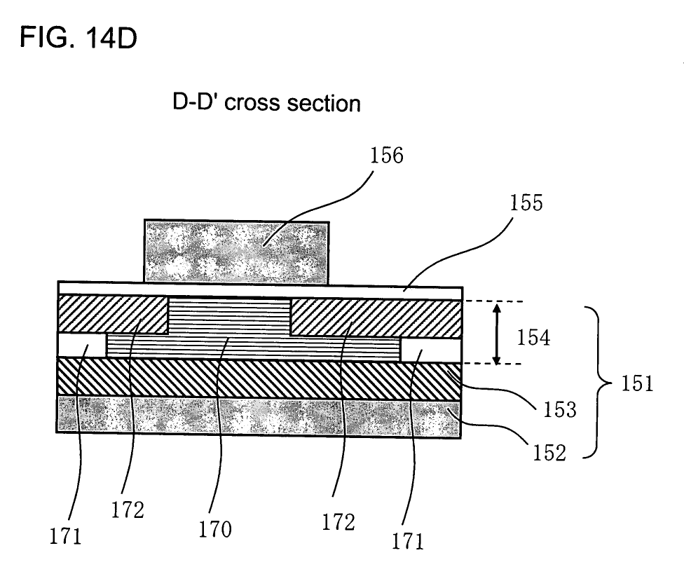

Next, the steps of forming the MOS type transistor A and the MOS type transistor B in the manufacturing process for a semiconductor memory device will be described with reference to FIGS. 14A to 14D. FIGS. 14A to 14D correspond to cross-sectional views taken on lines A-A′, B-B′, C-C′ and D-D′ of FIG. 3, respectively, and for illustration, the components described for FIGS. 3 to 7 are denoted by the same numbers.

First, isolation regions A and B were formed in the SOI type substrate 151, using the process for forming isolation regions having different depths as described above (when using process (a) as the step of forming the isolation region A and the isolation region B). Here, the isolation region A 160 (FIG. 14B) in the memory cell region was formed to a depth reaching the silicon oxide layer 153 in the SOI type substrate. The isolation region B 172 (FIGS. 14C, 14D) in the periphery circuit region was formed to a depth not reaching the silicon oxide layer 153 in the SOI type substrate.

Then, the upper silicon layer 154 in the SOI type substrate 151 was ion-implanted with a P-type dopant such as boron, to form a P-type well (FIG. 14C) in the periphery circuit region. Here, energy of ion implantation can be adjusted such that the P-type well 171 is formed under the isolation region 172 penetrating the isolation region 172 formed in the periphery circuit region.

Next, in the memory cell region, a P-type dopant was ion-implanted into the memory cell region using a photoresist film (not shown) as a mask to form a P-type diffusion layer in the body region (immediately beneath the gate electrode). Here, it is possible that a dopant concentration in the P-type well 171 is the same as that in the P-type diffusion layer 159 in the body region, and in such a case, the whole SOI type substrate can be ion-implanted without using a photoresist film.

Then, using a photoresist film as a mask, the periphery circuit region was implanted with an N-type dopant such as phosphorous to form an N-type well (170 in FIGS. 14C and 14D). Subsequently, when a threshold voltage of a transistor to be formed in the periphery circuit region must be adjusted, a dopant concentration was adjusted by ion-implanting an N-type or P-type dopant into the surface parts of the P-type well 171 and the N-type well 170 (not shown).

Next, a silicon oxide film as the gate insulating film 155 was formed by thermal oxidation on the upper silicon layer 154 in the SOI type substrate. Then, a two-layer structure film of a polycrystalline silicon film doped with an N-type dopant such as phosphorous and a high-melting metal film such as tungsten silicide (WSi) was formed as a gate electrode 156 for a transistor. Then, using a photoresist film (not shown), the gate electrodes A, B (156) were patterned.

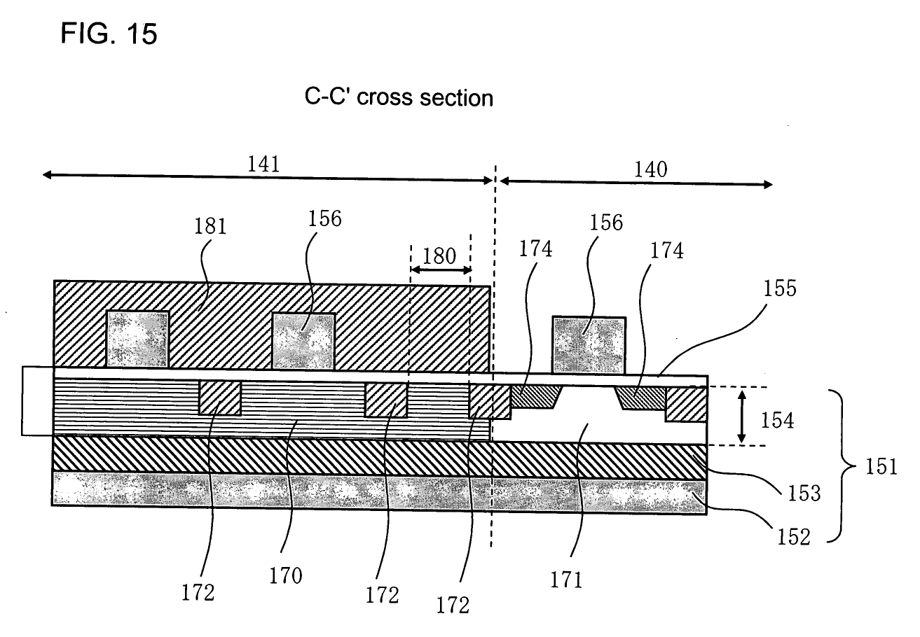

Subsequently, a photoresist film was formed such that it covered a region 141 (FIG. 3) where a P-channel type MOS transistor B is to be formed in the periphery circuit region. FIG. 15 is a cross-sectional view taken on line C-C′ of FIG. 3. In FIG. 15, 181 is a photoresist film. Here, the memory cell region is not covered by the photoresist film 181. In this state, an N-type dopant such as arsenic was ion-implanted to a concentration higher than that in the P-type well 171, to form an N-type diffusion layer region (source region B/drain region B) 174. During the ion implantation with the N-type dopant, an ion-implantation energy was set such that the bottom of the N-type diffusion layer region 174 did not reach the silicon oxide layer 153.

The dopant introduced by ion implantation must be treated at a high temperature in a later step for activation, during treatment at a high temperature, the implanted atoms migrated by diffusion. Thus, an ion-implantation energy was set such that the bottom of the N-type diffusion layer region 174 did not reach the silicon oxide layer 153, also taking this point into account. The N-type diffusion layer region 174 operates as a source region B/a drain region B in an N-channel type MOS transistor B.

In FIG. 15, the N-type diffusion layer region 180 formed in the N-type well 170 is also covered by the photoresist film 181, but the photoresist film 181 may be formed such that the N-type diffusion layer region 180 is exposed. In this case, by ion implantation, a concentration in the surface of the N-type diffusion layer region 180 becomes higher than that in the N-type well 170. It, therefore, becomes possible to reduce a contact resistance with an interconnection for drawing which is, in a later step, formed for fixing a potential of the N-type well 170. Then, after ion implantation, the photoresist film 181 was removed by known means.

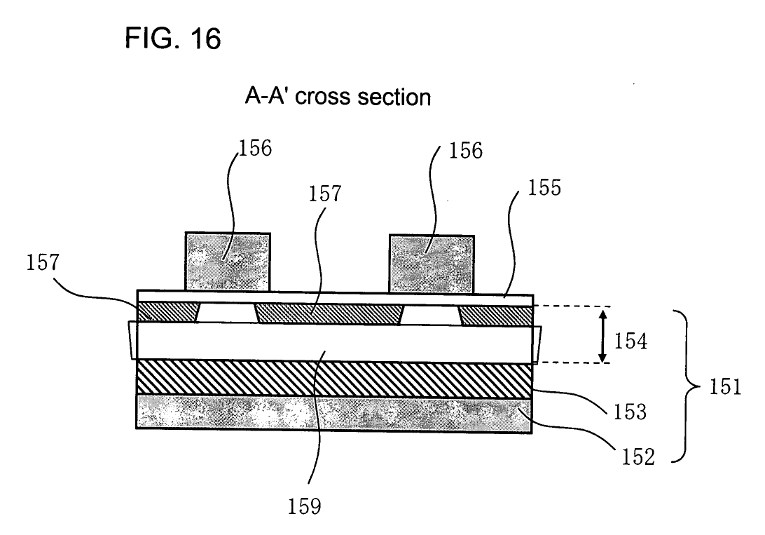

Meanwhile, during forming the above N-type diffusion layer region 174, in the memory cell region, the first N-type diffusion layer region 157 was formed by ion implantation as shown in a cross-section in FIG. 16 which corresponds to a cross-section taken on line A-A′ of FIG. 3. Although the N-type diffusion layer region 174 in the periphery circuit region and the first N-type diffusion layer region 157 are formed by the same step, they are denoted by the different numbers for clarity. As in the N-type diffusion layer region 174 (FIG. 15) formed in the periphery circuit region, the bottom of the first N-type diffusion layer region 157 does not reach the silicon oxide layer 153.

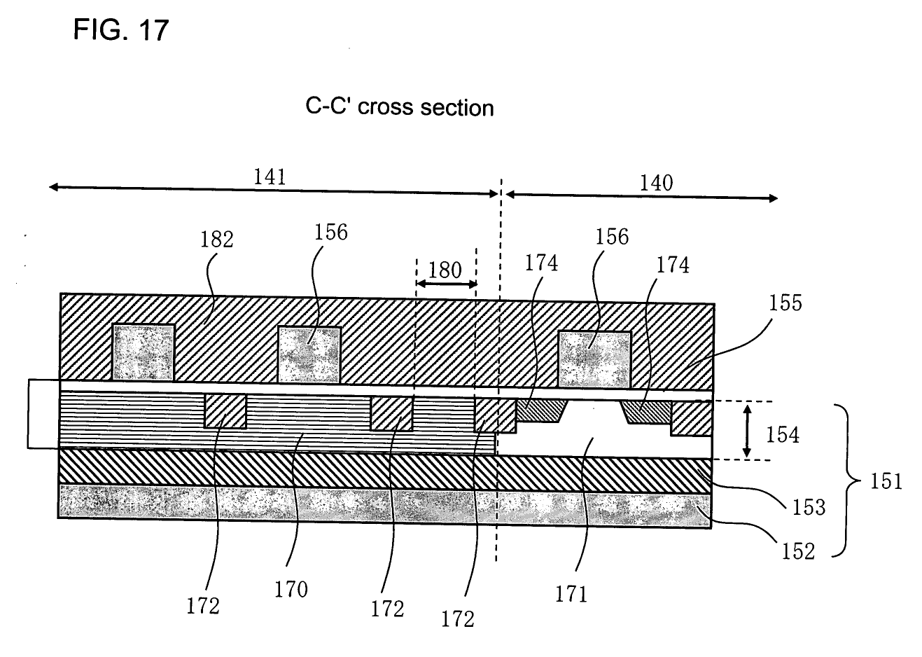

Then, as shown in a cross-section in FIG. 17 which corresponds to a cross-section taken on line C-C′ of FIG. 3, a photoresist film 182 was formed such that it covered the whole periphery circuit region. Here, the memory cell region is not covered by the photoresist film 182. In this state, an N-type dopant such as phosphorous was ion-implanted such that it reached a depth deeper than the bottom of the first N-type diffusion layer region 157 (FIG. 16) already formed, to form a second N-type diffusion layer region 158 (FIG. 4). An energy of the ion implantation was set such that the bottom of the second N-type diffusion layer region 158 reached the silicon oxide layer 153 (FIG. 4). Then, the photoresist film 182 was removed by known means. The memory cell region thus formed is surrounded by the first N-type diffusion layer region 157, the second N-type diffusion layer region 158 (the first N-type diffusion layer region 157 and the second N-type diffusion layer region 158 constitute a source region A/a drain region A) and the isolation region A 160 (FIG. 5). As a result, the body region immediately beneath the gate electrode is in a floating state.

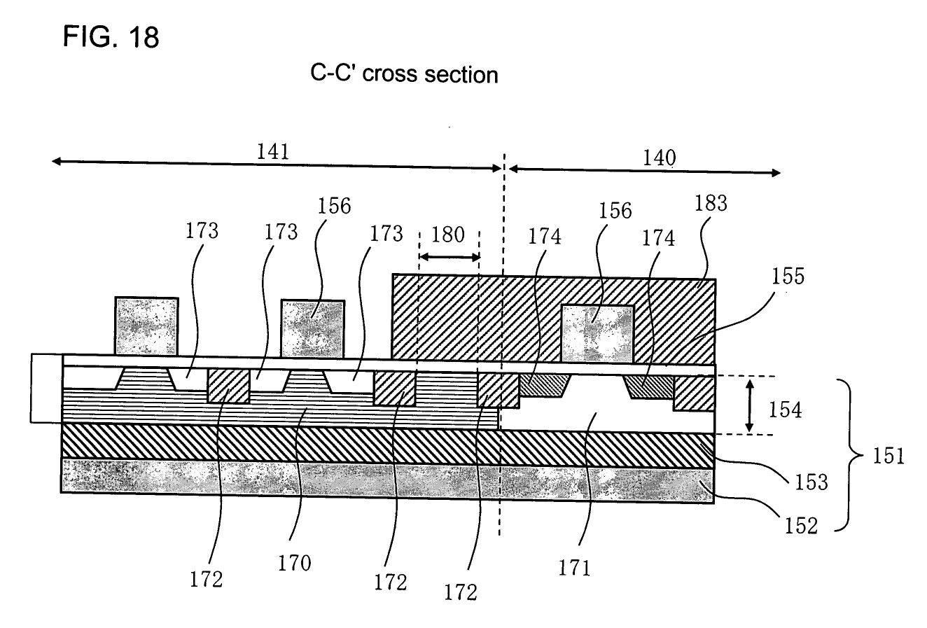

Next, as shown in a cross-section in FIG. 18 which corresponds to a cross-section taken on line C-C′ of FIG. 3, a photoresist film 183 was formed such that it covered the region 140 in the N-channel type MOS transistor B in the periphery circuit region and the N-type diffusion layer region 180. Then, a P-type dopant such as boron fluoride (BF₂) was ion-implanted to a concentration higher than that in the N-type well 170, to form a P-type diffusion layer region 173. The P-type diffusion layer region 173 operates as a source region B/a drain region B of a P-channel type MOS transistor B. Then, the photoresist film 183 was removed by known means. Subsequently, an interlayer insulating film, a contact hole for an interconnection, an interconnection layer for a bit line, an upper interconnection layer and so forth were formed to prepare a semiconductor memory device.

Although the gate insulating film is a silicon oxide film in the example described above, the material of the gate insulating film is not limited to the silicon oxide in the practice of present invention. For example, the gate insulating film may be a laminated film consisting of a silicon oxide film (SiO₂) and a silicon nitride film (Si₃N₄) or a hafnium(Hf)-containing oxide film.

The gate insulating film may be, in addition to the above materials, a metal oxide film, a metal silicate film, or a high-dielectric insulating film in which nitrogen is introduced into a metal oxide or silicate. The term, “high-dielectric insulating film” as used herein refers to an insulating film having a dielectric constant larger than that in SiO₂ which is widely used as a gate insulating film in a semiconductor device (about 3.6 for SiO₂). Typically, a high-dielectric insulating film has a dielectric constant of several tens to several thousands. Examples of a material which can be used for a high-dielectric insulating film include HfSiO, HfSiON, HfZrSiO, HfZrSiON, ZrSiO, ZrSiON, HfAlO, HfAlON, HfZrAlO, HfZrAlON, ZrAlO and ZrAlON.

Although the gate electrode has been described using a two-layer structure film consisting of a polycrystalline silicon film and a high-melting metal film, the gate electrode is not limited to the two-layer structure film. For example, it may be a monolayer film of polycrystalline silicon or a monolayer film of nickel silicide in which nickel (Ni) is introduced into a polycrystalline silicon.

In addition, a gate electrode material may be a silicide of at least one element selected from the group consisting of Ni, Cr, Cu, Ir, Rh, Ti, Zr, Hf, V, Ta, Nb, Mo and W. Specific examples of such a silicide include NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si and Pd₂Si.

### Example 2

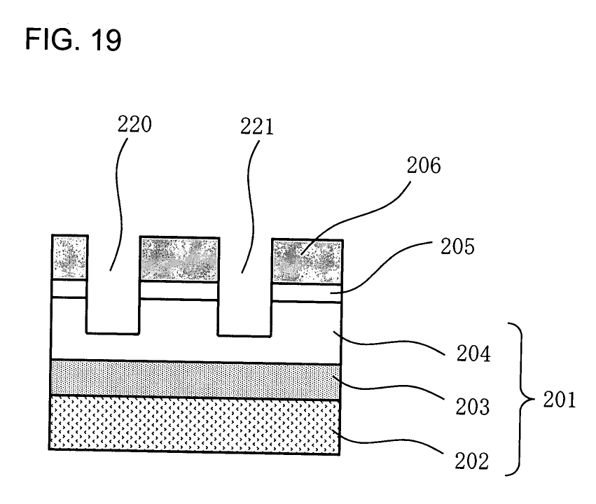

There will be described a second example of a manufacturing process for a semiconductor memory device with reference to the drawings. FIGS. 19 to 21 are cross-sectional views illustrating a process for forming two isolation regions having different depths in Example 2 (when using process (b) as the step of forming the isolation region A and the isolation region B). The components described for Example 1 are denoted by the same numbers.

As shown in FIG. 19, a silicon oxide film 205 and a silicon nitride film 206 were formed on an SOI type substrate 201 consisting of three layers: a lower silicon substrate (semiconductor substrate) 202, a silicon oxide layer (insulating layer) 203 and an upper silicon layer (semiconductor layer) 204. Then, patterning was conducted to form a trench (hole) 220 and a trench B 221 for an isolation region. Here, an etching depth of trench 220 in the silicon layer 204 is the same as that in trench 221, that is, an etching amount was adjusted such that in both trenches, etching did not reach the silicon oxide layer 203.

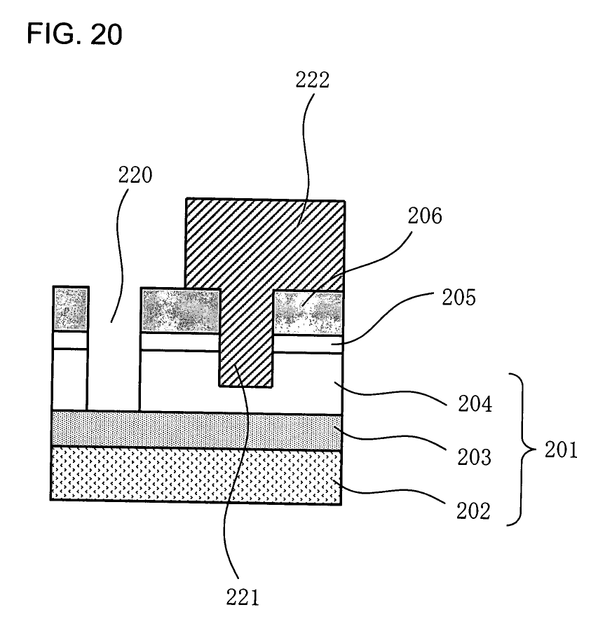

Then, as shown in FIG. 20, only the trench 221 for isolation formed in the region where a shallow isolation region B is to be formed was covered by the photoresist film 222. Next, the trench 220 formed in the region where a deep isolation region A is to be formed was left to be exposed. In this state, the silicon was etched using both silicon nitride film 206 and photoresist film 222 as a mask until the bottom of the trench 220 reached the silicon oxide layer 203.

When the silicon film is etched only once to form a trench pattern for a deep isolation region A, a photoresist film used for patterning is insufficiently resistant to prolonged etching. Therefore, for example, a silicon nitride film on which a photoresist film pattern has been transferred is commonly used as a hard mask. Furthermore, for forming a pattern with a smaller trench as a size reduction proceeds, it is necessary to improve a resolution by making a photoresist film thinner, and in such a case, resistance of a photoresist film to silicon etching is further reduced. Therefore, in Example 1 described above (FIGS. 8 to 13), there is illustrated a manufacturing process where silicon etching is conducted not directly using a photoresist film as a mask, but using a patterned silicon nitride film as a mask.

In contrast, in Example 2 herein, additional etching was conducted to the trench 220 in the silicon layer formed in the step shown in FIG. 19, so that an etching period is relatively shorter. Furthermore, a fine trench pattern has been already formed in the step of FIG. 19, and in the step of FIG. 20, regions not to be etched (for example, the whole periphery circuit region) may be covered by the photoresist film 222 all together. Therefore, a fine resolution is not needed for the photoresist film 222, so that the photoresist can be sufficiently thick. Thus, in FIG. 20, resistance of the photoresist film 222 to etching is of no matter and additional etching of the trench 220 can be easily conducted.

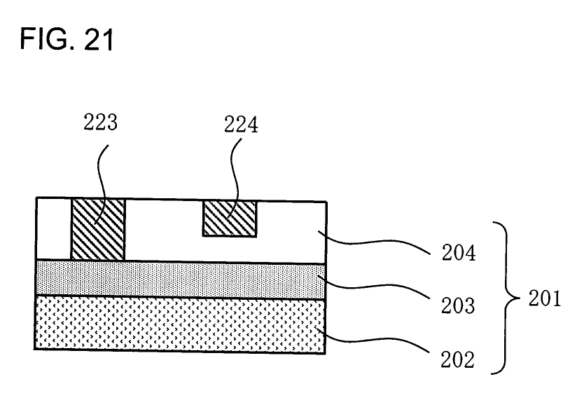

Then, the photoresist film 222 was removed, a silicon oxide film was formed for filling the trench, the surface layer was removed by CMP, and the silicon nitride film 206 and the silicon oxide film 205 were removed. Thus, as shown in FIG. 21, a deep isolation region A 223 and a shallow isolation region B 224 were formed. The isolation regions 223 and 224 were made of a silicon oxide film.

In this structure, the deep isolation region A 223 penetrates the upper silicon layer 204, and the bottom of the deep isolation region A 223 reaches the silicon oxide layer 203 as an insulating layer in the SOI type substrate. In contrast, the bottom of the shallow isolation region B 224 does not reach the silicon oxide layer 203.

By using the process for forming an isolation region illustrated in Example 2, a manufacturing procedure can be simplified in comparison with the process for an isolation region illustrated in Example 1, resulting in low-cost production. A semiconductor memory device was prepared by applying the process for forming an isolation region illustrated in Example 2 and, for the other steps, by following the procedure as illustrated in Example 1.

### Example 3

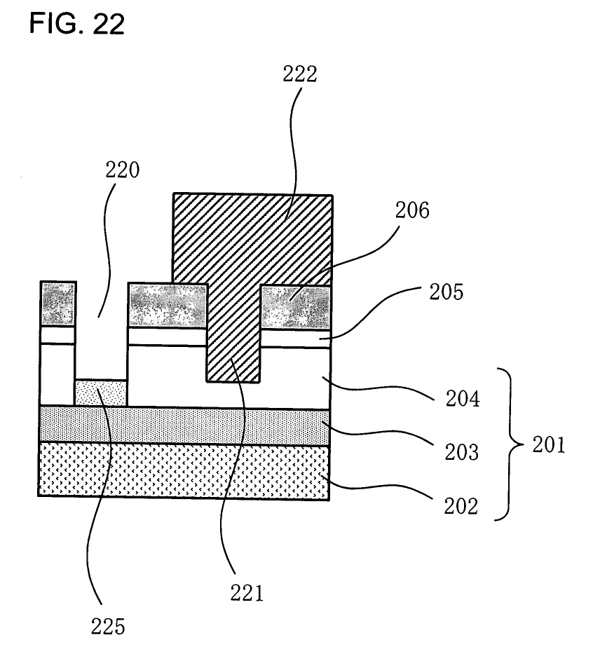

Next, Example 3 will be described with reference to the drawings. FIGS. 22 to 24 are cross-sectional views showing a process for forming two isolation regions having different depths in Example 3 (when using process (c) as the step of forming the isolation region A and the isolation region B). The components described in Example 2 are denoted by the same numbers.

First, to the step of FIG. 19 illustrated in Example 2, a trench A 220 and a trench B 221 for isolation region which had the same depth and did not reach the silicon oxide layer 203 were formed as described in Example 2.

Next, as shown in FIG. 22, only the trench B 221 for isolation formed in the region where a shallow isolation region B is to be formed was covered by the photoresist film 222. Then, a region C 225 from the bottom of the trench B 220 to the insulating layer in a thickness direction was ion-implanted with oxygen at a dose of 1×10¹⁵ to 1×10¹⁶ ions/cm² and an implantation energy of 20 to 100 KeV.

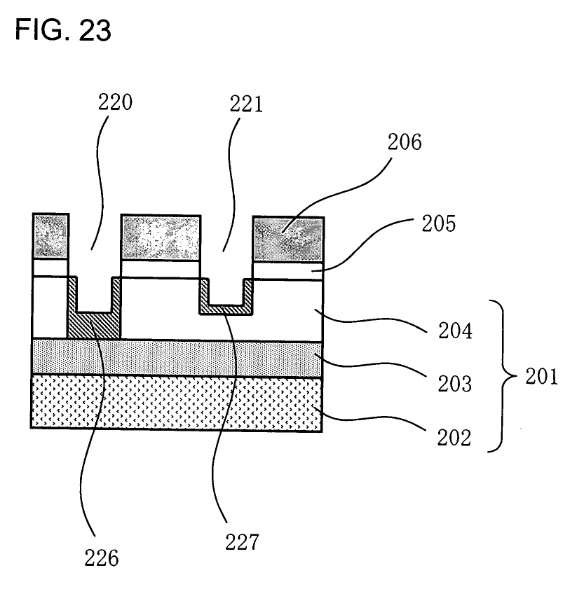

Then, as shown in FIG. 23, the photoresist film 222 was removed followed by thermal oxidation using dry oxygen gas under a high-temperature oxidizing atmosphere (temperature: 750° C. to 950° C.) or thermal oxidation using a mixed gas of oxygen and a non-oxidizing gas (for example, nitrogen) at a temperature of 900° C. to 1000° C. Thus, silicon oxide films 226 and 227 were formed in the inner walls of the trench A 220 and the trench B 221. Here, in the trench B 221, only a thin silicon oxide film 227 was formed on the bottom and the side. In contrast, in the trench A 220, an oxidation reaction rapidly proceeded in the region C where oxygen ions had been implanted, to form a very thick silicon oxide film 226 in the bottom. Therefore, by appropriately adjusting a depth of the initially formed trench A 220, a dose of implanted oxygen ions, a thermal oxidation time and so forth, the bottom silicon layer region of the trench A 220 could be converted into an insulator completely made of a silicon oxide film. The above conditions of oxygen ion implantation and of the thermal oxidation after the implantation are illustrative only, and they may be varied, depending on a device structure during production.

In the step of FIG. 22, when a dose of implanted oxygen ions are adjusted to be extremely high, only the bottom region of the trench A 220 can be converted into a silicon oxide film by just brief annealing under a non-oxidizing atmosphere in a later step, but an ion implantation equipment may be overloaded.

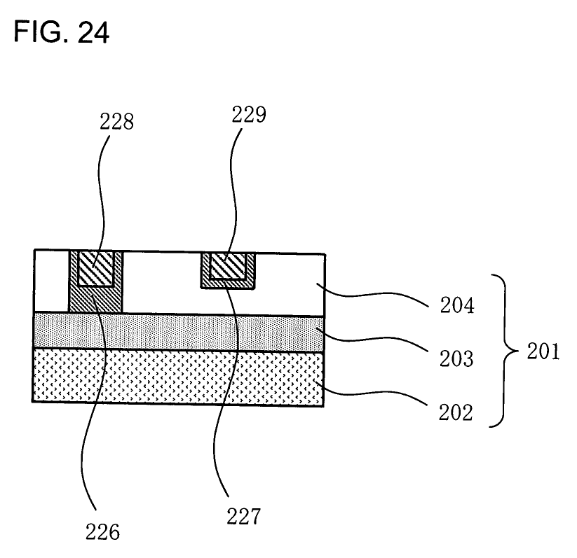

In contrast, in Example 3, oxygen-ion implantation and thermal oxidation are combined, so that a dose of implanted oxygen ions can be reduced. Therefore, a manufacturing equipment is not overloaded. Then, a silicon oxide film was formed by CVD such that it fills the trench A 220 and the trench B 221. Subsequently, as described for Example 2, an excessive part of the surface was removed to form the deep isolation region A 220 and the shallow isolation region B 221 as shown in FIG. 24.

In Example 3, the inside of the trench A 220 for isolation region have a two-layer structure of the silicon oxide film 228 formed by CVD and the silicon oxide film 226 formed by thermal oxidation. The inside of the trench B 221 for isolation region have a two-layer structure of the silicon oxide film 229 formed by CVD and the silicon oxide film 227 formed by thermal oxidation. The deep isolation region A 220 penetrates the upper silicon layer 204, and the bottom of the deep isolation region A 220 reaches the silicon oxide layer 203 through the silicon oxide film 226 formed by thermal oxidation. In contrast, the bottom of the shallow isolation region B 221 does not reach the silicon oxide layer 203.

A semiconductor memory device of the present invention was prepared by applying the process for forming an isolation region illustrated in Example 3 and, for the other steps, by following the procedure as illustrated in Example 1.

In the present invention, isolation regions A and B having different depths are formed on a semiconductor device formed on the same chip. Therefore, a process for forming isolation regions having different depths is not limited to those disclosed in Examples 1, 2 and 3, but such regions formed by an alternative process can be applied to a semiconductor memory device of the present invention. Furthermore, a process for forming an isolation region is not limited to a process using STI.

A depth of the isolation region B in the present invention may be appropriately selected as long as it is not in contact with the insulating layer in the SOI type substrate, but the smaller its difference from the depth of the isolation region A is, the easier processing is. It is, therefore, preferable that a depth of the isolation region B from the surface of the semiconductor layer in a thickness direction has a length of a half or more of the thickness of the semiconductor layer.

### Example 4

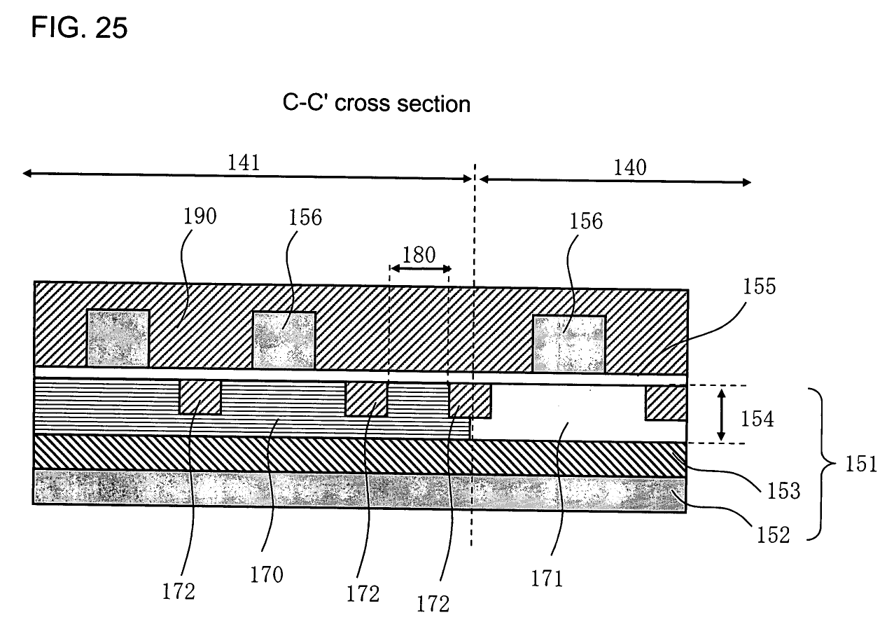

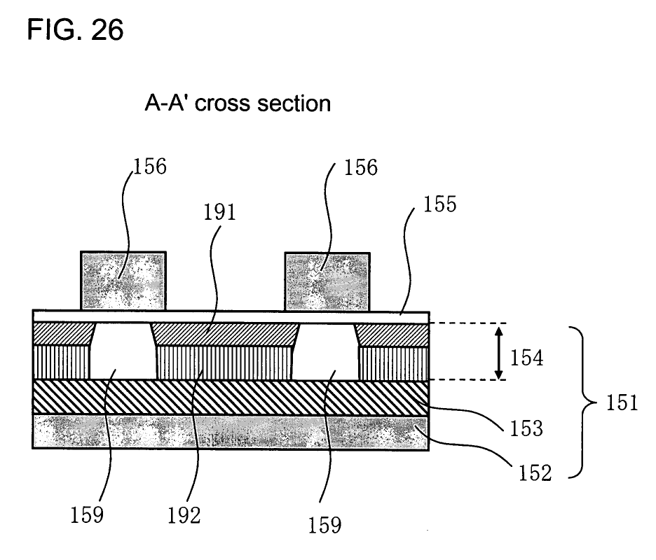

There will be described Example 4 with reference to the drawings. FIGS. 25 and 26 are cross-sectional views illustrating a process for forming an N-type diffusion layer region in Example 4. The components described in Example 1 are denoted by the same numbers.

First, to the step of forming a gate electrode on an SOI type substrate, the procedure as described for Example 1 was conducted to prepare the structure shown in FIGS. 14A to 14D. FIG. 25 is a cross-sectional view which corresponds to a cross-sectional view of the periphery circuit region taken on line C-C′ of FIG. 3. Then, the whole periphery circuit region was covered by a photoresist film 190. FIG. 26 is a cross-sectional view which corresponds to a cross-sectional view of the memory cell region taken on line A-A′ of FIG. 3. Here, the memory cell region is not covered by a photoresist film.

In this state, first, arsenic as an N-type dopant was ion-implanted under the conditions of an implantation energy of 20 to 200 KeV and a high concentration (a dose of 5×10¹⁵ to 1×10¹⁶ ions/cm²), to form a first N-type diffusion layer region 191. During this ion implantation, an implantation energy was adjusted depending on a film thickness of the upper silicon layer in the SOI type substrate, to form the first N-type diffusion layer 191 near the surface of the silicon layer 154 while not reaching the silicon oxide layer 153.

Then, phosphorous as an N-type dopant was ion-implanted under the conditions of an implantation energy of 100 to 800 KeV and a low concentration (7×10¹² to 3×10¹³ ions/cm²), to form a second N-type diffusion layer region 192. During the ion implantation, an implantation energy was adjusted, depending on a film thickness of the upper silicon layer in the SOI type substrate, so that the bottom of the second N-type diffusion layer 192 reached the silicon oxide layer 153.

Although the boundary between the first N-type diffusion layer region 191 and the second N-type diffusion layer region 192 is distinguishably indicated for clear description in FIG. 26, the boundary is unclear because practically dopant atoms contained in the individual diffusion layers are mixed near the boundary. However, although different atoms were ion-implanted into the first N-type diffusion layer region 191 and the second N-type diffusion layer region 192, both of them are an N-type dopant, and therefore, near the boundary, a total concentration of the ion-implanted dopants just gradually changes, which does not affect the characteristics of the present invention in this example. In the present invention, when referring to a dopant concentration in the first diffusion layer and the second diffusion layer, it indicates a dopant concentration in the part except the region near the boundary of these layers where dopant atoms are mixed. In the present invention, even when between these layers there is a region where dopant atoms are mixed as described above, the mixed region is thin, and, therefore, the first diffusion layer and the second diffusion layer is substantially close each other and it can be regarded that there is a second diffusion layer under the first diffusion layer.

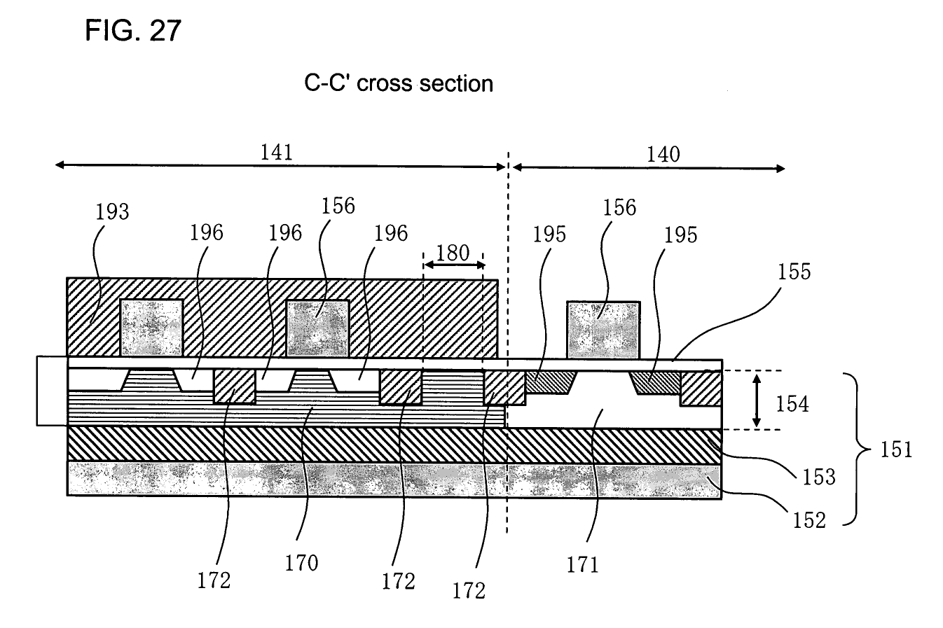

Next, the photoresist film 190 (FIG. 25) which had been formed covering the periphery circuit region was removed and a new photoresist film 193 was formed, covering the memory cell region and a region where a P-channel type MOS transistor is to be formed in the periphery circuit region. As shown in FIG. 27, using it as a mask, into the periphery circuit region, an N-type dopant such as arsenic was ion-implanted to a lower concentration than that in the first N-type diffusion layer region formed in the memory cell region (about 1×10¹⁵ ions/cm²) at an implantation energy of 20 to 50 KeV. Thus, an N-type diffusion layer region 195 was formed, which operates a source region B/a drain region B in an N-channel type MOS transistor B. Then, again in a similar manner, the memory cell region and a region where an N-channel type MOS transistor is to be formed in the periphery circuit region were covered by a photoresist film. Next, into the region of the P-channel type MOS transistor B in the periphery circuit region, a P-type dopant such as boron fluoride (BF₂) was ion-implanted to a concentration almost equivalent to that in the source region B/the drain region B in the N-channel type MOS transistor B (about 1×10¹⁵ ions/cm²) at an implantation energy of 20 to 50 KeV. Thus, a P-type diffusion layer region 196 was formed, which operates as a source region B/a drain region B. During forming the N-type diffusion layer region 195 and the P-type diffusion layer region 196, an ion-implantation energy was adjusted to prevent the bottom of the diffusion layer from reaching the silicon oxide layer 153.

In Example 4, the N-type diffusion layers in the memory cell region and in the periphery circuit region is separately formed. Therefore, in each of the memory cell region and the periphery circuit region, a dopant concentration and a depth (a set ion-implantation energy) can be adjusted to be optimal in the N-type diffusion layer region. In other words, for example, As described here, a dopant concentration in the first N-type diffusion layer region in the memory cell region can be made higher than that in the N-type diffusion layer region in the periphery circuit region. Thus, in the memory cell region, impact ionization needed for memory operation can be efficiently initiated to generate a large number of holes. Furthermore, a dopant concentration in the second N-type diffusion layer region in the memory cell region is set to be considerably lower than that in the first N-type diffusion layer region. Thus, when transferring the generated holes downward by applying an appropriate potential to the gate electrode A, a leak current can be so minimized that a time needed for refreshing stored data can be increased. Furthermore, in the periphery circuit region, a concentration and a depth in the source region B/the drain region B can be set to be optimal, regardless of the memory cell region. Thus, a high-performance memory device can be easily achieved.

The number of ion implantation used for forming the N-type diffusion layer region in the memory cell region is not limited to two as in Example 4, but while changing a implantation dose and an implantation energy, such implantation can be conducted three times or more to carefully control a concentration distribution in the diffusion layer. Furthermore, phosphorous may be used in place of arsenic as an N-type dopant used for forming the first N-type diffusion layer.

Furthermore, it is not necessary that the source region B/the drain region B in the periphery circuit region has the same dopant concentration in an N-channel type MOS transistor and a P-channel type MOS transistor, but the dopand concentration may differ between the N-channel type MOS transistor and the P-channel type MOS transistor.

### Example 5

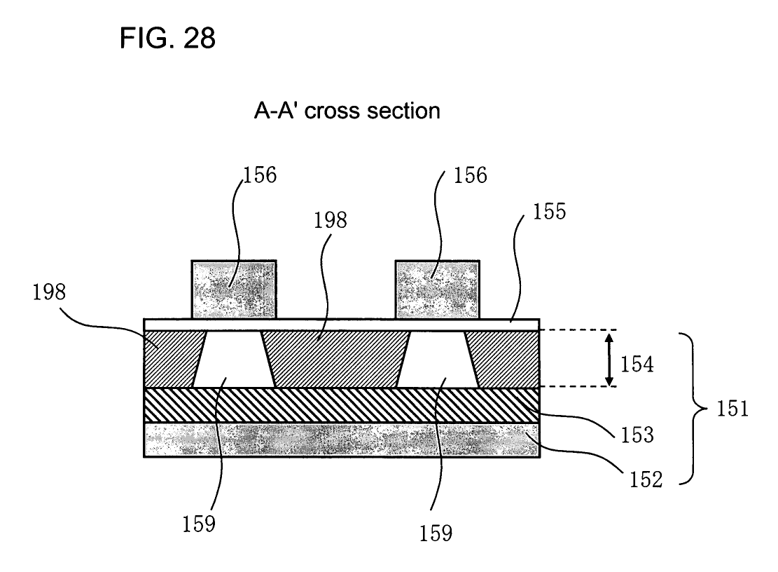

Example 5 will be described with reference to the drawings. First, the procedure in Example 4 was conducted to the step of forming a gate electrode, and then a periphery circuit region was covered by a photoresist film 190 as shown in FIG. 25. FIG. 28 is a cross-sectional view which corresponds to a cross-sectional view of a memory cell region taken on line A-A′ of FIG. 3. Here, the memory cell region is not covered by the photoresist film.

In this state, phosphorous as an N-type dopant was ion-implanted at a concentration of about 1×10¹⁵ ions/cm², and then the photoresist film was removed. Then, it was annealed under a nitrogen gas atmosphere at a high temperature (about 750 to 850° C.), to form an N-type diffusion layer region 198. Here, an annealing time was appropriately adjusted for transferring and diffusing phosphorous, so that the bottom of the N-type diffusion layer 198 reached the silicon oxide layer 153.

Then, as described in Example 4, an N-type diffusion layer and a P-type diffusion layer which operate as a source region B/drain region B of a transistor in a periphery circuit region were formed such that the bottom of the diffusion layer did not reach the silicon oxide layer 153 in the SOI type substrate (FIG. 27).

In this example, since the N-type diffusion layer in the memory cell region was formed by a single ion implantation, the number of ion implantation needed for production can be reduced in comparison with Example 4 described above. Furthermore, since the high-temperature annealing for forming the diffusion layer in the memory cell region is conducted before forming the diffusion layer for the source region B/the drain region B of the transistor in the periphery circuit region, the high-temperature annealing does not adversely affected the properties of the transistor in the periphery circuit region.

It is possible to combine the process for forming a diffusion layer region described in Examples 4 and 5, and the process for forming an isolation region described in Examples 2 and 3. Furthermore, the present invention may be combined with a conventional procedure for improving performance and reliability of a transistor, that is, conversion of a source region/a drain region in a transistor into an LDD (Lightly Doped Drain) or silicidation of the surface of a source region/a drain region, without deterioration in any of the features of the present invention.

The present invention may be applied not only a case where one chip has only a function as a DRAM, but also a case where a memory cell of a capacitorless DRAM and a circuit having a common logic function are formed on the same chip (a mixed DRAM chip).

Although the present invention has been described with reference to Examples, the present invention is not limited to the above examples. The constitution and the details of the present invention can be changed in various ways which can be understood by one skilled in the art within the technical limits of the present invention.

What is claimed is:

1. A semiconductor memory device, comprising:
(1) an SOI type substrate in which a semiconductor substrate, an insulating layer and a semiconductor layer are laminated in order;
(2) a first region comprising
(i) an isolation region A formed extending from the surface of the semiconductor layer to the insulating layer in a thickness direction, and
(ii) an MOS type transistor A, comprising
a semiconductor region A formed within the semiconductor layer which is insulated and isolated by the isolation region A,
a gate electrode A formed over the semiconductor region A, and
a source region A/ a drain region A formed in both sides sandwiching the gate electrode A within the semiconductor region A, wherein the source region A/ the drain region A extends from the surface of the semiconductor region A to the insulating layer in a thickness direction; and
(3) a second region comprising
(i) an isolation region B formed extending from the surface of the semiconductor layer to a depth not reaching the insulating layer in a thickness direction, and
(ii) an MOS type transistor B, comprising
a semiconductor region B formed within the semiconductor layer which is insulated and isolated by the isolation region B,
a gate electrode B formed over the semiconductor region B, and
a source region B/ a drain region B formed in both sides sandwiching the gate electrode B within the semiconductor region B, wherein the source region B/ the drain region B extends from the surface of the semiconductor region B to a depth not reaching the insulating layer in a thickness direction.

2. A semiconductor memory device, comprising:
(1) an SOI type substrate in which a semiconductor substrate, an insulating layer and a semiconductor layer are laminated in order;
(2) a first region comprising
(i) an isolation region A formed by filling a trench A penetrating the semiconductor layer to the insulating layer in a thickness direction, with an insulating material, and
(ii) an MOS type transistor A, comprising
a semiconductor region A formed within the semiconductor layer which is insulated and isolated by the isolation region A,
a gate electrode A formed over the semiconductor region A, and
a source region A/drain region A formed in both sides sandwiching the gate electrode A within the semiconductor region A, wherein the source region A/drain region A extends over the whole length in a thickness direction of the semiconductor region A and whose bottom is contact with the insulating layer; and
(3) a second region comprising
(i) an isolation region B formed by filling a trench B extending from the surface of the semiconductor layer to a depth not reaching the insulating layer in a thickness direction, with an insulating material, and
(ii) an MOS type transistor B, comprising
a semiconductor region B formed within the semiconductor layer which is insulated and isolated by the isolation region B,
a gate electrode B formed over the semiconductor region B, and
a source region B/ a drain region B formed in both sides sandwiching the gate electrode B within the semiconductor region B, wherein the bottom of the source region B/ the drain region B does not reach the insulating layer.

3. The semiconductor memory device as claimed in claim 1, wherein
the first region is a memory cell region, and
the second region is a periphery circuit region.

4. The semiconductor memory device as claimed in claim 1, wherein
the MOS type transistor A is constituted such that one MOS type transistor A has multiple threshold voltage states different from each other and a given threshold voltage state can be held for a given period.

5. The semiconductor memory device as claimed in claim 1, wherein
the source region A/the drain region A comprises a first diffusion layer formed in the surface side of the semiconductor layer and a second diffusion layer formed in the side of the insulating layer beneath the first diffusion layer, and
a dopant concentration in the first diffusion layer is different from a dopant concentration in the second diffusion layer.

6. The semiconductor memory device as claimed in claim 1, wherein
the MOS type transistor A is constituted such that a region where a channel is to be formed is in an electrically floating state, and
the MOS type transistor B is constituted such that a region where a channel is to be formed has a fixed potential.

7. The semiconductor memory device as claimed in claim 1, wherein
the semiconductor substrate and the semiconductor layer constituting the SOI type substrate are made of a silicon semiconductor,
the first region comprises an N-channel type MOS transistor as the MOS type transistor A, and
the second region comprises an N-channel type MOS transistor and a P-channel type MOS transistor as the MOS type transistor B.

8. The semiconductor memory device as claimed in claim 1, wherein
a depth of the isolation region B from the surface of the semiconductor layer in a thickness direction has a length of a half or more of the thickness of the semiconductor layer.

9. The semiconductor memory device as claimed in claim 2, wherein
the first region is a memory cell region, and
the second region is a periphery circuit region.

10. The semiconductor memory device as claimed in claim 2, wherein
the MOS type transistor A is constituted such that one MOS type transistor A has multiple threshold voltage states different from each other and a given threshold voltage state can be held for a given period.

11. The semiconductor memory device as claimed in claim 2, wherein
the source region A/the drain region A comprises a first diffusion layer formed in the surface side of the semiconductor layer and a second diffusion layer formed in the side of the insulating layer beneath the first diffusion layer, and
a dopant concentration in the first diffusion layer is different from a dopant concentration in the second diffusion layer.

12. The semiconductor memory device as claimed in claim 2, wherein
the MOS type transistor A is constituted such that a region where a channel is to be formed is in an electrically floating state, and
the MOS type transistor B is constituted such that a region where a channel is to be formed has a fixed potential.

13. The semiconductor memory device as claimed in claim 2, wherein
the semiconductor substrate and the semiconductor layer constituting the SOI type substrate are made of a silicon semiconductor,
the first region comprises an N-channel type MOS transistor as the MOS type transistor A, and
the second region comprises an N-channel type MOS transistor and a P-channel type MOS transistor as the MOS type transistor B.

14. The semiconductor memory device as claimed in claim 2, wherein
a depth of the isolation region B from the surface of the semiconductor layer in a thickness direction has a length of a half or more of the thickness of the semiconductor layer.

15. A process for manufacturing a semiconductor memory device comprising an SOI type substrate where a semiconductor substrate, an insulating layer and a semiconductor layer are laminated in order, comprising:
preparing the SOI type substrate;
forming an isolation region A extending within the semiconductor layer from the surface of the semiconductor layer to the insulating layer in a thickness direction and an isolation region B extending within the semiconductor layer from the surface of the semiconductor layer to a depth not reaching the insulating layer in a thickness direction;
forming, within a semiconductor region A which is insulated and isolated by the isolation region A within the semiconductor layer, an MOS type transistor A comprising a source region A/a drain region A extending from the surface of the semiconductor region A to the insulating film in a thickness direction; and
forming, within a semiconductor region B which is insulated and isolated by the isolation region B within the semiconductor layer, an MOS type transistor B comprising a source region B/a drain region B extending from the surface of the semiconductor region B to a depth not reaching the insulating layer in a thickness direction.

16. The process for manufacturing a semiconductor memory device as claimed in claim 15, wherein
the step of forming the isolation region A and the isolation region B comprises the steps of:
forming a trench A penetrating within the semiconductor layer from the surface of the semiconductor layer to a depth reaching the insulating layer in a thickness direction;
forming a trench B extending within the semiconductor layer from the surface of the semiconductor layer to a depth not reaching the insulating layer in a thickness direction; and
filling the trench A and the trench B with an insulating material.

17. The process for manufacturing a semiconductor memory device as claimed in claim 15, wherein
the step of forming the isolation region A and the isolation region B comprises the steps of:
forming a hole and a trench B extending within the semiconductor layer from the surface of the semiconductor layer to a depth not reaching the insulating layer in a thickness direction;
extending the hole within the semiconductor layer in a thickness direction to form a trench A having a depth reaching the insulating layer; and
filling the trench A and the trench B with an insulating material.

18. The process for manufacturing a semiconductor memory device as claimed in claim 15, wherein
the step of forming the isolation region A and the isolation region B comprises the steps of:
forming a trench A and a trench B extending within the semiconductor layer from the surface of the semiconductor layer to a depth not reaching the insulating layer in a thickness direction;
introducing oxygen atoms into a region C within the semiconductor layer from the bottom of the trench A to the insulating layer in a thickness direction;
thermally oxidizing the semiconductor layer under an oxidizing atmosphere at a high temperature to convert the region C into an insulator and to form an oxide film in the inner walls of the trench A and the trench B; and
filling the trench A and the trench B with an insulating material.

19. The process for manufacturing a semiconductor memory device as claimed in claim 15, wherein
the step of forming the MOS type transistor A comprises the steps of:
forming a gate electrode A over the semiconductor region A; and
forming the source region A/ the drain region A in both sides sandwiching the gate electrode A within the semiconductor region A, and
the step of forming the MOS type transistor B comprises the steps of:
forming a gate electrode B over the semiconductor region B; and
forming the source region B/ the drain region B in both sides sandwiching the gate electrode B within the semiconductor region B.

20. The process for manufacturing a semiconductor memory device as claimed in claim 15, wherein
the step of forming the MOS type transistor A comprises the steps of:
forming a gate electrode A over the semiconductor region A;
ion-implanting a first conductive type dopant into both sides sandwiching the gate electrode A within the semiconductor region A, to form a first diffusion layer extending from the surface of the semiconductor region A to a depth not reaching the insulating layer in a thickness direction; and
ion-implanting a first conductive type dopant into both sides sandwiching the gate electrode A within the semiconductor region A, to form a second diffusion layer in a region from the bottom of the first diffusion layer to the insulating layer in a thickness direction, and forming the source region A/ the drain region A comprising the first diffusion layer and the second diffusion layer,
the step of forming the MOS type transistor B comprises the steps of:
forming a gate electrode B over the semiconductor region B; and
ion-implanting a first conductive type dopant into both sides sandwiching the gate electrode B within the semiconductor region B to form the source region B/ the drain region B.

21. The process for manufacturing a semiconductor memory device as claimed in claim 20, wherein
the step of forming the MOS type transistor B further comprises the step of ion-implanting a second conductive type dopant into both sides sandwiching the gate electrode B within the semiconductor region B to form a third diffusion layer extending from the surface of the semiconductor region B to a depth not reaching the insulating layer in a thickness direction as a part of the source region B/ the drain region B.

22. The process for manufacturing a semiconductor memory device as claimed in claim 20, wherein
the ion implantation in the step of forming the MOS type transistor A is conducted such that a dopant concentration in the first diffusion layer becomes higher than a dopant concentration in the second diffusion layer.
